(19) United States
(12) Patent Application Publication
(10) Pub. No.: US 2025/0341441 A1
(43) Pub. Date: Nov. 6, 2025

(54) WATERPROOFING INSPECTION APPARATUS

(71) Applicants: Samsung Electronics Co., Ltd., Suwon-si (KR); HOYEON CO., LTD, Gumi-si (KR)

(72) Inventors: Seonggwan PARK, Suwon-si (KR); Jaekwang LEE, Gumi-si (KR); Hyunwook WOO, Suwon-si (KR); Jeongjae YOO, Suwon-si (KR)

(21) Appl. No.: 19/269,946

(22) Filed: Jul. 15, 2025

Related U.S. Application Data
(63) Continuation of application No. PCT/KR2023/019862, filed on Dec. 5, 2023.

(30) Foreign Application Priority Data
Jan. 20, 2023 (KR) 10-2023-0008934
May 9, 2023 (KR) 10-2023-0059585

(51) Int. Cl. G01M 3/32; H05K 5/02

(52) U.S. Cl. CPC G01M 3/3272; H05K 5/0214

(57) ABSTRACT

A waterproofing test device is provided. The waterproofing test device includes one or more clip devices including a sealing pad configured to seal at least one an air vent hole provided in an electronic device by mechanical fastening with the electronic device, wherein the sealing pad has one side of a connection hose connected to a rear surface of a surface sealed with the at least one air vent hole, and is configured to inject external air suctioned through the connection hose into the electronic device through the at least one air vent hole in response to a pressure change on an opposite side of the connection hose, or to discharge internal air suctioned from the electronic device through the at least one air vent hole to an outside through the connection hose in response to the pressure change on the opposite side of the connection hose.

### CROSS-REFERENCE TO RELATED APPLICATION(S)

This application is a continuation application, claiming priority under 35 U.S.C. § 365 (c), of an International application No. PCT/KR2023/019862, filed on Dec. 5, 2023, which is based on and claims the benefit of a Korean patent application number 10-2023-0008934, filed on Jan. 20, 2023, in the Korean Intellectual Property Office, and of a Korean patent application number 10-2023-0059585, filed on May 9, 2023, in the Korean Intellectual Property Office, the disclosure of each of which is incorporated by reference herein in its entirety.

### JOINT RESEARCH AGREEMENT

The disclosure was made by or on behalf of the below listed parties to a joint research agreement. The joint research agreement was in effect on or before the date the disclosure was made and the disclosure was made as a result of activities undertaken within the scope of the joint research agreement. The parties to the joint research agreement are 1) Samsung Electronics Co., Ltd, and 2) HOYEON CO., LTD.

### BACKGROUND

### 1. Field

The disclosure relates to a waterproofing test device for testing the waterproof status of an electronic device.

### 2. Description of Related Art

Electronic devices such as smartphones, portable multimedia players (PMPs), tablet PCs, or e-book readers are representative examples of electronic devices that are easy to carry by users. These electronic devices may be referred to as ‘portable electronic devices’. The portable electronic devices may allow users to access content more freely, without restrictions on location or time.

Since the portable electronic device is often used while being held by the user, it is more prone to water ingress damage compared to devices that are placed or fixed in one position. Typically, electronic devices contain components that are vulnerable to water exposure, making waterproof performance a key factor in determining product quality.

Accordingly, the electronic device is equipped with at least a basic level of water resistance sufficient for daily use, and its waterproof performance is tested before release or shipment.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a waterproofing test device for testing the waterproof status of an electronic device.

Additional aspects will be set forth in part in the description which follows and, in part, will be apparent from the description, or may be learned by practice of the presented embodiments.

In accordance with an aspect of the disclosure, a waterproofing test device is provided. The waterproofing test device includes one or more clip devices including a sealing pad configured to seal at least one air vent hole provided in an electronic device by mechanical fastening with the electronic device,

In an embodiment, wherein the sealing pad has one side of a connection hose connected to a rear surface of a surface sealed with the at least one air vent hole, and is configured to inject external air suctioned through the connection hose into the electronic device through the at least one air vent hole in response to a pressure change on an opposite side of the connection hose, or to discharge internal air suctioned from the electronic device through the at least one air vent hole to an outside through the connection hose in response to the pressure change on the opposite side of the connection hose.

According to an embodiment of the disclosure, the waterproofing test device for the electronic device includes a main body configured to change a pressure to inject external air into the electronic device or to suction internal air of the electronic device through at least one air vent hole provided in the electronic device in response to an external force.

According to an embodiment, the waterproofing test device includes a basic type clip device including a first sealing pad configured to seal with a first air vent hole, which is one of the at least one air vent hole, by mechanical fastening with the electronic device.

According to an embodiment, the waterproofing test device includes a common type clip device including a second sealing pad configured to seal with a second air vent hole, which is another one of the at least one air vent hole, by mechanical fastening with the electronic device.

In an embodiment, the main body includes a pressure adjustment part configured to discharge the external air filling an inner housing through an air hole or to fill the inner housing with the internal air suctioned through the air hole, in response to the external force.

In an embodiment, the first sealing pad is connected to an opposite side of a first connection hose having one side connected to the air hole, and include a passage for injecting the external air transferred through the first connection hose from the air hole into the electronic device through the first air vent hole, or for suctioning the internal air to be transferred through the first connection hose to the air hole from the electronic device through the first air vent hole.

In an embodiment, the second sealing pad is connected to an opposite side of a second connection hose having one side connected to the air hole, and include a passage for injecting the external air transferred through the second connection hose from the air hole into the electronic device through the second air vent hole, or for suctioning the internal air to be transferred through the second connection hose to the air hole from the electronic device through the second air vent hole.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a waterproofing test device according to an embodiment of the disclosure;

FIG. 2 is a plan view illustrating a main body included in a waterproofing test device according to an embodiment of the disclosure;

FIG. 3 is a front view illustrating a main body included in a waterproofing test device according to an embodiment of the disclosure;

FIG. 4 is a bottom view illustrating a main body included in a waterproofing test device according to an embodiment of the disclosure;

FIG. 5 is a right side view illustrating a main body included in a waterproofing test device according to an embodiment of the disclosure;

FIG. 6 is a plan view illustrating a basic type clip device included in a waterproofing test device according to an embodiment of the disclosure;

FIG. 7 is a front view illustrating a basic type clip device included in a waterproofing test device according to an embodiment of the disclosure;

FIG. 8 is a bottom view illustrating a basic type clip device included in a waterproofing test device according to an embodiment of the disclosure;

FIG. 9 is a left side view illustrating a basic type clip device included in a waterproofing test device according to an embodiment of the disclosure;

FIG. 10 is a rear perspective view illustrating a basic type clip device included in a waterproofing test device according to an embodiment of the disclosure;

FIG. 11 is a state diagram in which a basic type clip device included in a waterproofing test device is mounted on an electronic device to be tested according to an embodiment of the disclosure;

FIG. 12 is a plan view illustrating a common type clip device included in a waterproofing test device according to an embodiment of the disclosure;

FIG. 13 is a front view illustrating a common type clip device included in a waterproofing test device according to an embodiment of the disclosure;

FIG. 14 is a bottom view illustrating a common type clip device included in a waterproofing test device according to an embodiment of the disclosure;

FIG. 15 is a left side view illustrating a common type clip device included in a waterproofing test device according to an embodiment of the disclosure;

FIG. 16A is a see-through perspective view illustrating that a flat dedicated pad is attached to a common type clip device included in a waterproofing test device according to an embodiment of the disclosure;

FIG. 16B is a see-through perspective view illustrating that a cylindrical dedicated pad is attached to a common type clip device included in a waterproofing test device according to an embodiment of the disclosure;

FIG. 17 is a view illustrating a spring structure for determining a fixing force of an electronic device to be tested in a clip device according to an embodiment of the disclosure;

FIG. 18 is a structural view illustrating an anti-slip pad provided to fix an electronic device to be tested in a clip device according to an embodiment of the disclosure;

FIG. 19 or 20A, 20B, and 20C are views illustrating an operation example of a pressure adjustment part for changing an internal pressure of an electronic device to be tested in a waterproofing test device according to various embodiments of the disclosure;

FIG. 21 is a view illustrating an assembly structure for mounting a communication module for measuring pressure in a waterproofing test device according to an embodiment of the disclosure;

FIG. 22 is a cross-sectional view taken along line A-A′ illustrated in FIG. 21 according to an embodiment of the disclosure;

FIG. 23 is a perspective view illustrating a position adjustment part included in a clip device of a waterproofing test device according to an embodiment of the disclosure;

FIG. 24 is a view illustrating a rotating structure of a pad fixing part in a basic type clip device included in a waterproofing test device according to an embodiment of the disclosure; and

FIGS. 25A, 25B, 25C, and 25D are views illustrating an example of a test target device that may be tested by a waterproofing test device according to various embodiments of the disclosure.

Throughout the drawings, like reference numerals will be understood to refer to like parts, components, and structures.

### DETAILED DESCRIPTION

The following description with reference to the accompanying drawings sis provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

According to various embodiments of the disclosure, there may be provided a waterproofing test device capable of sealing a sealing pad with an air vent hole provided in a product under test based on a clip structure.

According to an embodiment, the waterproofing test device tests waterproof performance by injecting air through an inlet of a clip-type fixed connection hose structure, so that the tester may not only perform waterproofing test in a stable circumstance, but also facilitate the operation of a diagnostic program for waterproofing test.

The technical objects of the disclosure are not limited to the foregoing, and other technical objects may be derived by one of ordinary skill in the art from example embodiments of the disclosure.

Effects of the disclosure are not limited to the foregoing, and other unmentioned effects would be apparent to one of ordinary skill in the art from the following description. In other words, unintended effects in practicing embodiments of the disclosure may also be derived by one of ordinary skill in the art from example embodiments of the disclosure.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

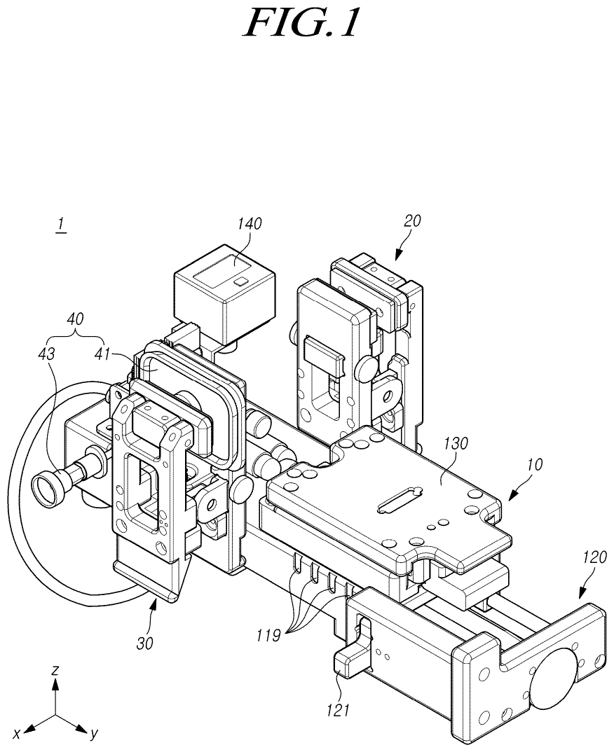

FIG. 1 is a perspective view illustrating a waterproofing test device 1 according to an embodiment of the disclosure.

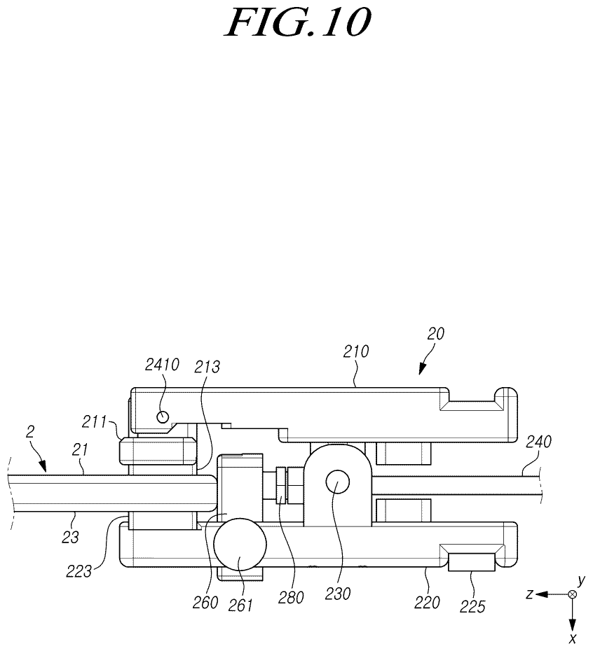

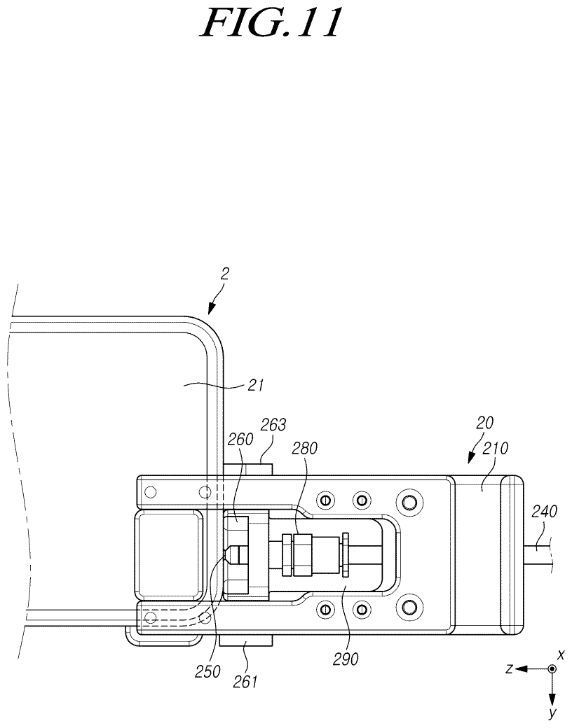

Referring to FIG. 1, a waterproofing test device 1 may include a main body 10 or at least one clip device 20 or 30. The main body 10 may inject air into an electronic device (e.g., an electronic device 2 of FIG. 10 or 11), which is a waterproofing test target, through the at least one clip device 20 or 30 in response to an external force. The main body 10 may suction the internal air of the electronic device 2, which is a waterproofing test target, through the at least one clip device 20 and 30 in response to an external force. The at least one clip device 20 and 30 may receive air discharged from the main body 10 through, e.g., the connection hose (tube) 169. The at least one clip device 20 and 30 may supply air suctioned from the electronic device 2 to the main body 10 through the connection hose 169. The connection hose 169 may provide, e.g., a flow path through which air may communicate in the forward or reverse direction between the main body 10 and the at least one clip device 20 and 30. One side of the connection hose 169 may be connected to a nozzle provided in the main body 10. The other side of the connection hose 169 may be connected to a nozzle provided in the at least one clip device 20 or 30.

The at least one clip device 20 and 30 may include at least one of a basic type clip device 20 and a common type clip device 30. For example, the basic type clip device 20 may be mounted on one side surface of the main body 10. For example, the common type clip device 30 may be mounted on one side surface of the main body. The basic type clip device 20 and the common type clip device 30 may be disposed to face each other on two opposite side surfaces of the main body 10. For example, the basic type clip device 20 or the common type clip device 30 may be provided with the magnet on one surface thereof. In an embodiment, the basic type clip device 20 or the common type clip device 30 may be attached to a metal material provided in the main body 10 by the magnet provided on one surface thereof. For example, the basic type clip device 20 or the common type clip device 30 may be provided with a metal material on one surface thereof. The basic type clip device 20 or the common type clip device 30 may be attached to a magnet provided in the main body 10 by the metal material provided on one surface thereof.

The basic type clip device 20 may have a structure in which the electronic device 2, which is a waterproofing test target, is vertically held using a clip using elasticity by a member such as a spring. The basic type clip device 20 may have an air pad at a position facing an air vent hole of the electronic device 2 that has been vertically held using the clip. The air pad included in the basic type clip device 20 may be, for example, designed to reduce (depressurize) the internal pressure of the electronic device 2 by sealing the air vent hole of the electronic device 2 that has been vertically held using the clip. The air pad included in the basic type clip device 20 may be designed to increase (pressurize) the internal pressure of the electronic device 2 by sealing the air vent hole of the electronic device 2 that has been vertically held using the clip. For example, the basic type clip device 20 may be suitable for use for a waterproofing test of the electronic device 2 including an air vent hole in a side surface thereof. The basic type clip device 20 may be open in at least one of the upper or lower direction of the air pad to facilitate air communication for waterproofing test. For example, the basic type clip device 20 may be open in at least one of the upper or lower direction of the air pad so that the sealing state of the air vent hole included in the electronic device 2 and the air pad may be visually identified. The basic type clip device 20 may be open in at least one of the left or right direction of the air pad to facilitate air communication for waterproofing test. In an example, the basic type clip device 20 may be open in at least one of the left or right direction of the air pad so that the sealing state of the air vent hole included in the electronic device 2 and the air pad may be visually identified.

The common type clip device 30 may have a structure in which the electronic device 2, which is a waterproofing test target, is vertically held using a clip using elasticity by a member such as a spring. The common type clip device 30 may have an air pad at a position facing the air vent hole of the electronic device 2 that has been vertically held using the clip. The air pad included in the common type clip device 30 may be designed to reduce (depressurize) the internal pressure of the electronic device 2 by sealing the air vent hole of the electronic device 2 that has been vertically held using the clip. The air pad included in the common type clip device 30 may be designed to increase (pressurize) the internal pressure of the electronic device 2 by sealing the air vent hole of the electronic device 2 that has been vertically held using the clip. For example, the common type clip device 30 may be suitable for use for waterproofing test of the electronic device 2 including the air vent hole in the side surface thereof. In an embodiment, the common type clip device 30 may be open in at least one of the upper or lower direction of the air pad to facilitate air communication for waterproofing test. For example, the common type clip device 30 may be open in at least one of the upper or lower direction of the air pad so that the sealing state of the air vent hole included in the electronic device 2 and the air pad may be visually identified. The common type clip device 30 may be open in at least one of the left or right direction of the air pad to facilitate air communication for waterproofing test. For example, the common type clip device 30 may be open in at least one of the left or right direction of the air pad so that the sealing state of the air vent hole included in the electronic device 2 and the air pad may be visually identified.

According to an example, the common type clip device 30 may be equipped with a dedicated air pad 40 near the clip for holding the electronic device 2 which is the waterproofing test target. The dedicated air pad 40 may be designed to be suitable for waterproofing test of the electronic device 2 having an air vent hole in an upper or lower surface thereof. The dedicated air pad 40 may be replaced in consideration of the position or size of the air vent hole provided in the electronic device 2. For example, if a waterproofing test is performed on the electronic device 2 having air vent holes widely spread out on the upper or lower surface, the common type clip device 30 may be equipped with a first dedicated air pad 41, which is a flat air pad that may cover the widely spread air vent hole. For example, if a waterproofing test is performed on the electronic device 2 having one air vent hole disposed in the upper or lower surface, the common type clip device 30 may be equipped with a second dedicated air pad 43, which is a cylindrical air pad that may cover the one air vent hole. One of the first dedicated air pad 41 and the second dedicated air pad 43 may be mounted on the common type clip device 30, and the other may be mounted on a cradle provided on a side surface of the main body 10. For example, the first dedicated air pad 41 may be mounted on the common type clip device 30, and the second dedicated air pad 43 may be mounted on the cradle provided on the side of the main body 10.

The main body 10 may include a pressure adjustment part 120, a module mounting part 130, or a barometer 140. A stroke fixing part 119 may be provided on a side surface of the main body 10. The stroke fixing part 119 may include, e.g., stroke fixing recesses spaced apart at predetermined intervals. In an embodiment, the stroke fixing part 119 may fix an adjustment handle part 121 so that the pressure adjustment part 120 may maintain a constant pressure (e.g., a pressurizing amount or a depressurizing amount). For example, the pressure may be maintained relatively low by the pressure adjustment part 120 as the adjustment handle part 121 is positioned in the +y direction among the plurality of stroke fixing recesses included in the stroke fixing part 119. For example, the pressure may be maintained relatively high by the pressure adjustment part 120 as the adjustment handle part 121 is positioned in the −y direction among the plurality of stroke fixing recesses included in the stroke fixing part 119.

The pressure adjustment part 120 may discharge air as an discharge pressure acts as the control handle part 121 proceeds in the +y direction without fixing it to the stroke fixing part 119. The pressure adjustment part 120 may suction air as a suction pressure acts as the control handle part 121 proceeds in the −y direction without fixing it to the stroke fixing part 119. When the internal pressure of the electronic device 2, which is a waterproofing test target, changed by air discharge or air suction, is to be maintained, the adjustment handle part 121 may be fixed by being inserted into the stroke fixing recess provided at the current position.

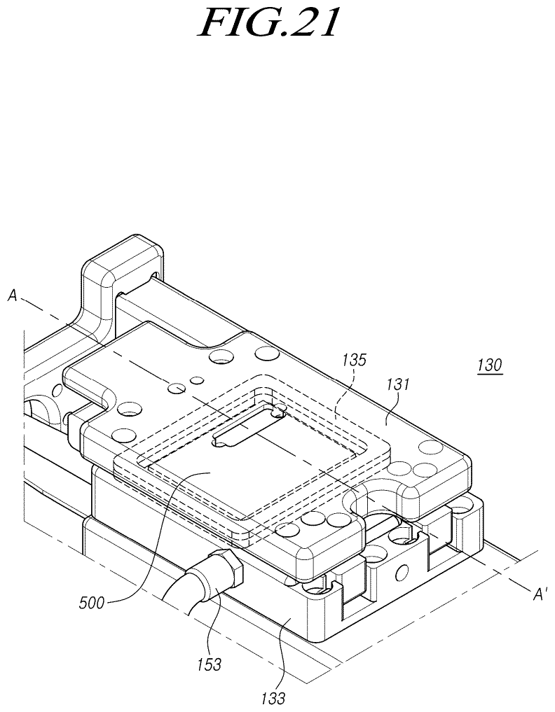

A module mounting part 130 may be equipped with a functional module (e.g., the Bluetooth barometer module 500 of FIG. 21). For example, the module mounting part 130 may have a clip shape, where pressing a handle provided on one side opens the opposite side. In this case, the user may press the handle of the module mounting part 130 to open the other side and mount the functional module (e.g., the Bluetooth barometer module 500 of FIG. 21) in a housing provided inside. In an embodiment, the functional module mounted on the module mounting part 130 may transfer pressure information due to air discharged from the pressure adjustment part 120 or suctioned by the pressure adjustment part 120 to an external device. The module mounting part 130 may be connected to a passage through which air is discharged from, or suctioned into, the pressure adjustment part 120 for pressure measurement, through an air hose.

The barometer 140 may display pressure information due to air discharged from the pressure adjustment part 120 or suctioned by the pressure adjustment part 120. The barometer 140 may be a digital barometer that measures pressure in a digital manner. The barometer 140 may be connected to a passage through which air is discharged from, or suctioned into, the pressure adjustment part 120 for pressure measurement, through an air hose.

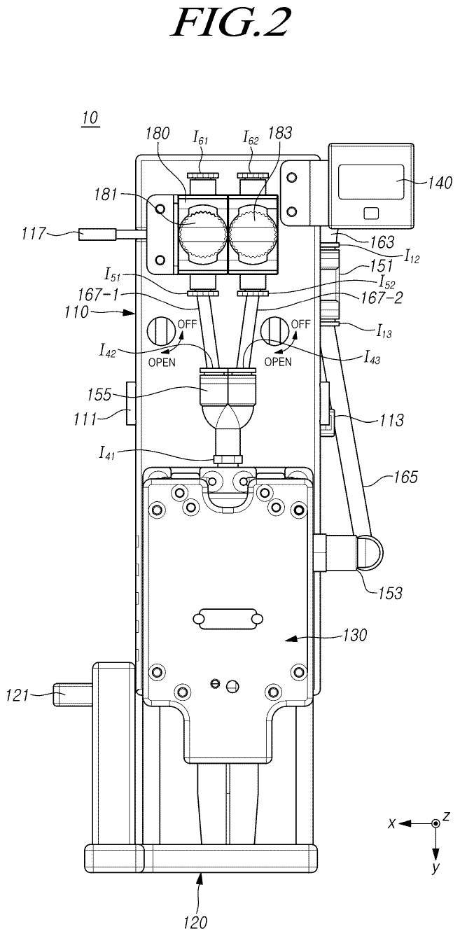

FIG. 2 is a plan view illustrating a main body (e.g., the main body 10 of FIG. 1) included in a waterproofing test device (e.g., the waterproofing test device 1 of FIG. 1) according to an embodiment of the disclosure.

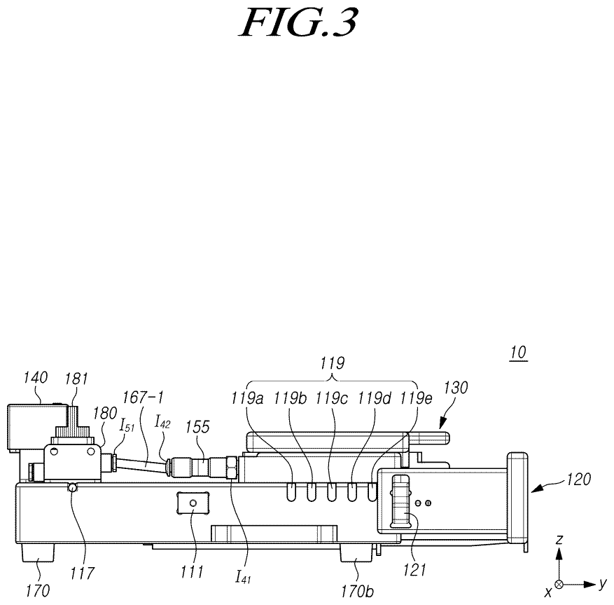

FIG. 3 is a front view illustrating a main body (e.g., the main body 10 of FIG. 1) included in a waterproofing test device (e.g., the waterproofing test device 1 of FIG. 1) according to an embodiment of the disclosure.

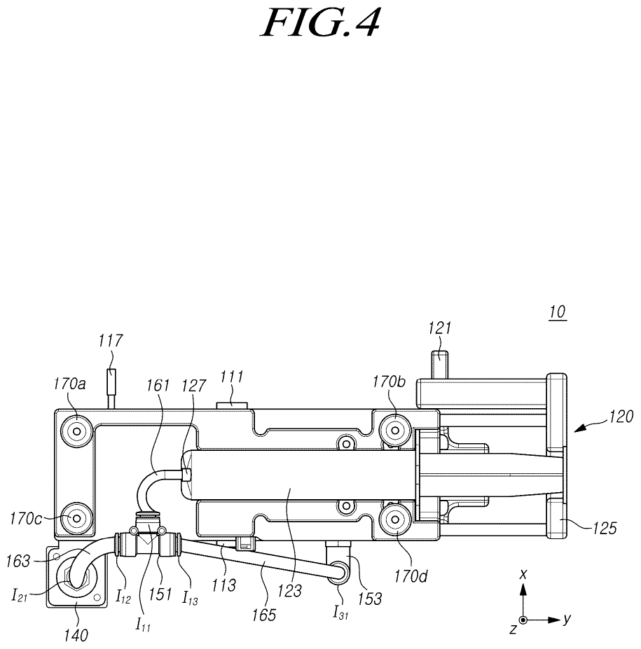

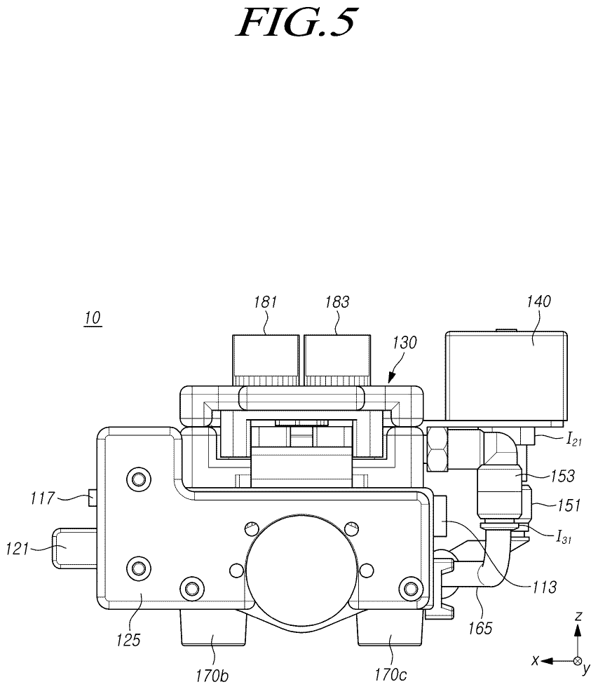

FIG. 4 is a bottom view illustrating a main body (e.g., the main body 10 of FIG. 1) included in a waterproofing test device (e.g., the waterproofing test device 1 of FIG. 1) according to an embodiment of the disclosure.

FIG. 5 is a right side view illustrating a main body (e.g., the main body 10 of FIG. 1) included in a waterproofing test device (e.g., the waterproofing test device 1 of FIG. 1) according to an embodiment of the disclosure.

Referring to FIGS. 2 to 5, the main body 10 may include a frame 110, a pressure adjustment part 120, a module mounting part 130, a barometer 140, or an air adjustment part 180. The pressure adjustment part 120 may be included in the lower surface portion of the frame 110. The module mounting part 130 may be included in the upper surface portion of the frame 110. The barometer 140 may be included in a side portion of the frame 110. In an embodiment, the air adjustment part 180 may be included in the upper surface of the frame 110. One of two opposite side surfaces of the frame 110 may include a pad mounting part 117 capable of mounting and storing a dedicated air pad (e.g., the first dedicated air pad 41 or the second dedicated air pad 43 of FIG. 1). A first clip mounting part 111 or a second clip mounting part 113 may be included in each of two opposite side surfaces of the frame 110. For example, a common type clip device (e.g., the common type clip device 30 of FIG. 1) may be mounted on the first clip mounting part 111. For example, a basic type clip device (e.g., the basic type clip device 20 of FIG. 1) may be mounted on the second clip mounting part 113. A plurality of pads 170 (i.e., 170a, 170b, 170c, and 170d) for preventing slipping may be included on the lower surface of the frame 110.

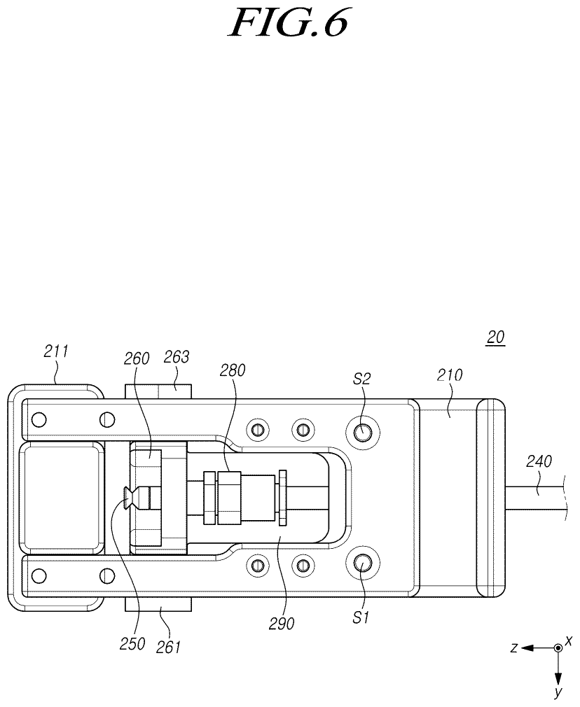

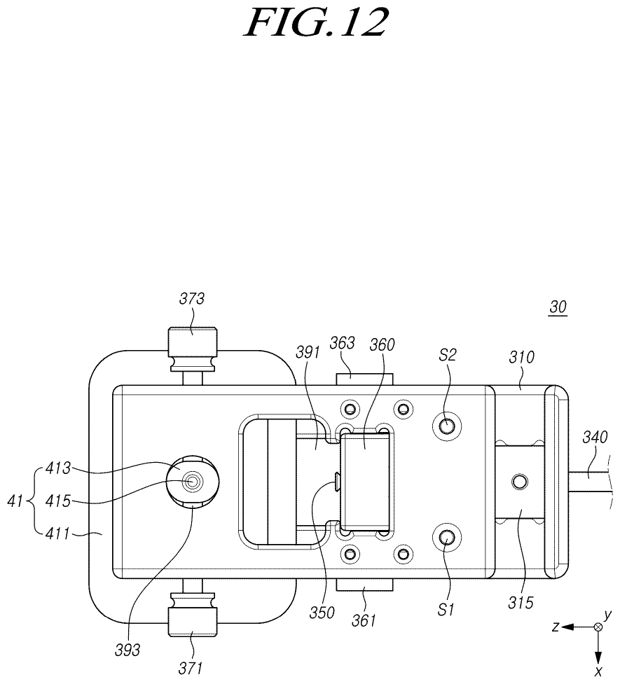

According to an embodiment, the air adjustment part 180 may include a first air adjustment valve 181 or a second air adjustment valve 183. The air adjustment part 180 may include a 1-1th hose connection tube I51 or a 1-2th hose connection tube 152 for forming a flow path with the pressure adjustment part 180. The 1-1th hose connection tube I51 or the 1-2th hose connection tube I52 may be disposed on the same side surface facing the same direction (e.g., +y direction). The air adjustment part 180 may include a 1-3th hose connection tube I61 or a 1-4th hose connection tube I62 for forming a flow path with a clip device (e.g., the basic type clip device 20 of FIG. 1 or the common type clip type 30). The 1-3th hose connection tube I61 or the 1-4th hose connection tube I62 may be disposed on the same side surface facing the same direction (e.g., −y direction). In an example, a hose (e.g., the hose 240 of FIG. 6 or the hose 340 of FIG. 12) may have one end connected to the 1-3th hose connection tube I61 and the other end connected to a basic type clip device (e.g., the basic type clip device 20 of FIG. 1) which is one of the clip devices. For example, a hose (e.g., the hose 240 of FIG. 6 or the hose 340 of FIG. 12) may have one end connected to the 1-4th hose connection tube I62 and the other end connected to a common type clip device (e.g., the common type clip type 30 of FIG. 1) which is one of the clip devices.

The first air adjustment valve 181 may adjust the amount or intensity of air flowing in the flow path between the 1-1th hose connection tube I51 and the 1-3th hose connection tube I61. The first air adjustment valve 181 may increase the amount or intensity of air flowing in the flow path between the 1-1th hose connection tube I51 and the 1-3th hose connection tube I61 in response to clockwise rotation. The first air adjustment valve 181 may reduce the amount or intensity of air flowing in the flow path between the 1-1th hose connection tube I51 and the 1-3th hose connection tube I61 in response to counterclockwise rotation.

The second air adjustment valve 183 may adjust the amount or intensity of air flowing in the flow path between the 1-2th hose connection tube I52 and the 1-4th hose connection tube I62. The second air adjustment valve 183 may increase the amount or intensity of air flowing in the flow path between the 1-2th hose connection tube I52 and the 1-4th hose connection tube I62 in response to clockwise rotation. The second air adjustment valve 183 may reduce the amount or intensity of air flowing in the flow path between the 1-2th hose connection tube I52 and the 1-4th hose connection tube I62 in response to counterclockwise rotation.

According to an embodiment, the module mounting part 130 may include a second air hose connection part 153 or a third air hose connection part 155. The second air hose connection part 153 may be connected to one end of the third air hose 165 for forming a flow path with the pressure adjustment part 180. The third air hose connection part 155 may include a 2-1th hose connection tube I41 for forming a flow path with the module mounting part 130. The third air hose connection part 155 may include a 2-2th hose connection tube I42 or a 2-3th hose connection tube I43 to be connected to one end of the fourth air hose 167-1 and 167-2 for forming a flow path with the 1-1th hose connection tube I51 or the 1-2th hose connection tube I52 of the air adjustment part 180.

According to another embodiment, a stroke fixing part 119 may be included in one of two opposite side surfaces of the frame 110 included in the main body 10. The stroke fixing part 119 may include, e.g., stroke fixing recesses 119a, 119b, 119c, 119d, and 119e spaced apart at predetermined intervals. The spacing interval of the stroke fixing recesses 119a, 119b, 119c, 119d, and 119e may be determined in consideration of an internal pressure to be generated in the electronic device (e.g., the electronic device 2 of FIG. 10) for waterproofing test. The internal pressure may be set for each type of electronic device 2, for example.

The pressure adjustment part 120 may include an adjustment handle part 121, a syringe 123, or a syringe mounting part 125. The adjustment handle part 121 may be integrally formed with the syringe mounting part 125. The syringe 123 may be mounted on the syringe mounting part 125. The syringe 123 may include a nozzle 127 to discharge or suction air. The nozzle 127 may be connected to one end of the first air hose 161 for forming a flow path with the 3-1th hose connection tube I11 of the first air hose connection part 151. The other end of the first air hose 161 may be connected to the 3-1th hose connection tube I11 of the first air hose connection part 151.

According to an embodiment, the first air hose connection part 151 may include a 3-1th hose connection tube I11, a 3-2th hose connection tube I12, or a 3-3th hose connection tube I13. The 3-1th hose connection tube I11 may be connected to the nozzle 127 included in the syringe 123 by the first air hose 161. The 3-2th hose connection tube I12 may be connected to the fourth hose connection tube I21 included in the barometer 140 by the second air hose 163. In an embodiment, the 3-3th hose connection tube I13 may be connected to the fifth hose connection tube I31 included in the second air hose connection part 153 by the third air hose 165. The fifth hose connection tube I31 may be included in the module mounting part 130.

According to the above-described hose connection structure, the flow path of the air discharged by the nozzle 127 of the syringe 123 included in the pressure adjustment part 120 may be formed through the first air hose connection part 151, the second air hose connection part 153, the module mounting part 130, the third air hose connection part 155, and the air adjustment part 180 to the clip device 20, 30.

According to the above-described hose connection structure, the flow path of the air suctioned by the nozzle 127 of the syringe 123 included in the pressure adjustment part 120 may be formed through the air adjustment part 180, the third air hose connection part 155, the module mounting part 130, the second air hose connection part 153, and the first air hose connection part 151 to the nozzle 127 after suctioned from the electronic device 2 by the clip device 20, 30.

FIG. 6 is a plan view illustrating a basic type clip device (e.g., the basic type clip device 20 of FIG. 1) included in a waterproofing test device (e.g., the waterproofing test device 1 of FIG. 1) according to an embodiment of the disclosure.

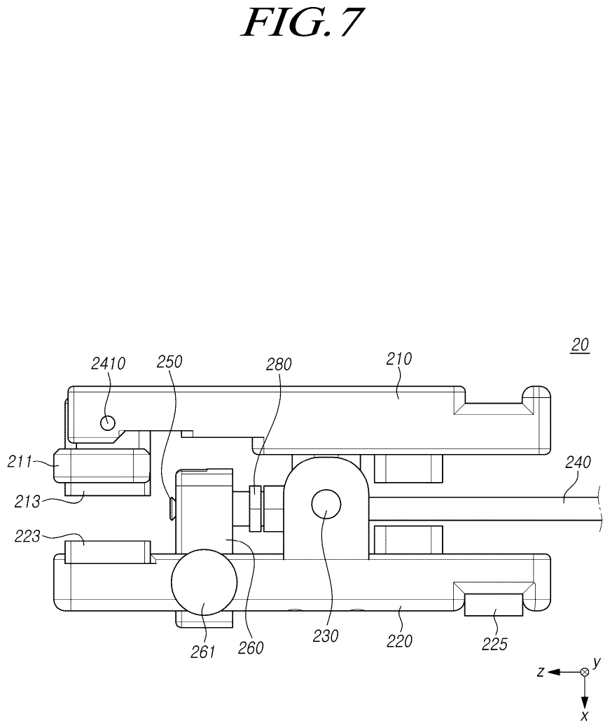

FIG. 7 is a front view illustrating a basic type clip device (e.g., the basic type clip device 20 of FIG. 1) included in a waterproofing test device (e.g., the waterproofing test device 1 of FIG. 1) according to an embodiment of the disclosure.

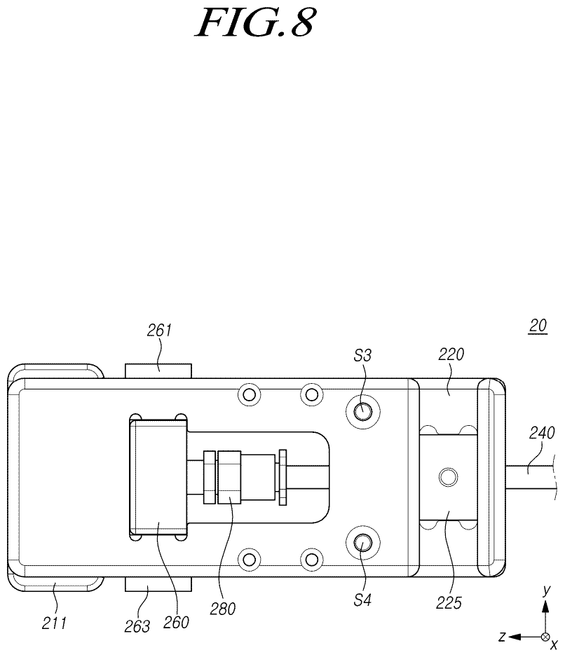

FIG. 8 is a bottom view illustrating a basic type clip device (e.g., the basic type clip device 20 of FIG. 1) included in a waterproofing test device (e.g., the waterproofing test device 1 of FIG. 1) according to an embodiment of the disclosure.

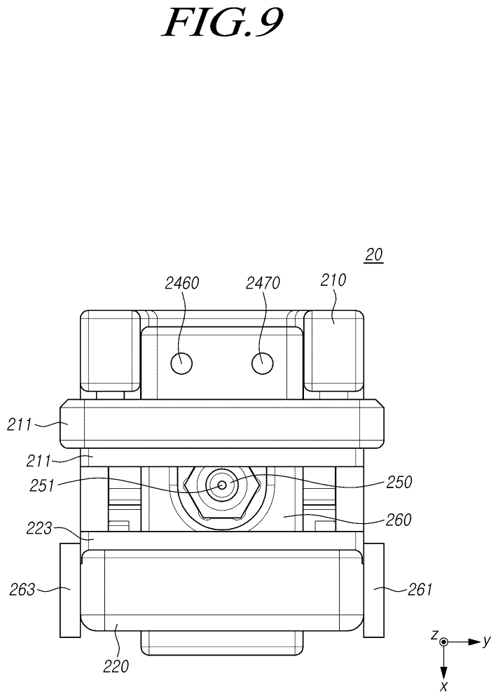

FIG. 9 is a left side view illustrating a basic type clip device (e.g., the basic type clip device 20 of FIG. 1) included in a waterproofing test device (e.g., the waterproofing test device 1 of FIG. 1) according to an embodiment of the disclosure.

Referring to FIGS. 6 to 9, the basic type clip device 20 may include a first clip member 210, a second clip member 220, or a first rotation shaft 230 for rotatably connecting the first clip member 210 and the second clip member 220. The first clip member 210 may be an upper clip member. The second clip member 220 may be a lower clip member. The first rotational shaft 230 may be positioned substantially near the middle or at a point between the middle and the handle side where an external force acts in the first clip member 210 and/or the second clip member 220.

The first clip member 210 may have two first fastening protrusions formed substantially near the middle in the length direction. The first fastening protrusions may be formed to face two opposite side surfaces from near the middle of the first clip member 210. The first fastening protrusion may include a first fastening hole at substantially the same height. The first fastening hole may be used for coupling with the second clip member 220 by the first rotation shaft 230.

According to an embodiment, the second clip member 220 may have two second fastening protrusions formed substantially near the middle in the length direction. The second fastening protrusions may be formed to face two opposite side surfaces from near the middle of the second clip member 220. The second fastening protrusion may include a second fastening hole at substantially the same height. The second fastening hole may be used for coupling with the first clip member 210 by the first rotation shaft 230.

For example, the first fastening protrusion included in the first clip member 210 may be inserted into the second fastening protrusion included in the second clip member 220. In this case, the first fastening hole provided in the first fastening protrusion and the second fastening hole provided in the second fastening protrusion may be aligned in a straight line. This will allow the first clip member 210 and the second clip member 220 to rotate around the first rotation shaft 230 as the first rotation shaft 230 passes through the first fastening hole and the second fastening hole.

When the handle near the first clip member 210 and/or the handle near the second clip member 220 is pressed by an external force, the first clip member 210 and/or the second clip member 220 may rotate around the first rotation shaft 230. In this case, the rotation around the first rotation shaft 230 may cause a movement, such as the opening of the clip, of the opposite part of the handle. In an example, the vicinity of the handle of the first clip member 210 may rotate in the +x direction around the first rotation axis 230, and the vicinity of the handle of the second clip member 220 may rotate in the −x direction around the first rotation axis 230.

When the external force is removed, the first clip member 210 and/or the second clip member 220 may rotate around the first rotation shaft 230. In this case, rotation around the first rotation shaft 230 may cause a movement, such as closing of the clip, of the opposite part of the handle. For example, the vicinity of the handle of the first clip member 210 may rotate in the −x direction around the first rotation shaft 230, and the vicinity of the handle of the second clip member 220 may rotate in the +x direction around the first rotation shaft 230.

For example, the first clip member 210 may include a first pad 213 at a portion opposite to a handle part on which an external force is applied for the purpose of rotation. The first pad 213 may be disposed in a direction facing the second clip member 220. The first pad 213 may fix one surface (e.g., the upper surface (e.g., the first surface 21 of FIG. 10)) of an electronic device (e.g., the electronic device 2 of FIG. 10), which is a waterproofing test target. The first pad 213 may be, e.g., formed of a urethane material. The first pad 213 may be mounted on the first clip member 210 using a pad fixing part 211. The pad fixing part 211 may include, e.g., a guide having one surface coupled to the first clip member 210 and the other surface inserted near the edge of the first pad 213 to be mounted or detached.

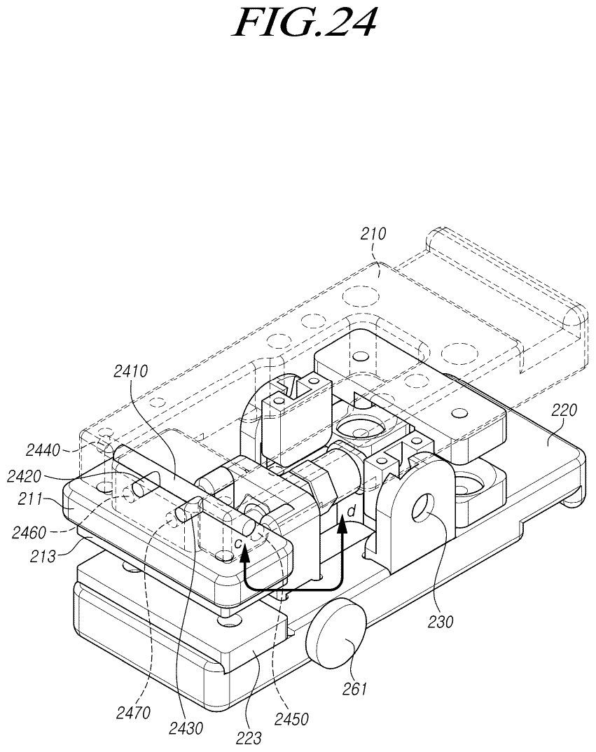

According to an embodiment, the pad fixing part 211 may be fitted into the first clip member 210 by a shaft that operates as a rotation axis (e.g., the rotation axis 2410 of FIG. 24) on the y axis. The pad fixing part 211 may rotate in a predetermined direction (e.g., in direction c or direction d of FIG. 24) by the rotation shaft 2410. The pad fixing part 211 may rotate around the rotation shaft 2410, e.g., when the rotation shaft 2410 is fixed by fitting into a fitting recess (e.g., the fitting recesses 2440 and 2450 of FIG. 24) provided in the first clip member 210. For example, when the rotation shaft 2410 is fitted into the first clip member 210 to be rotatable, the pad fixing part 211 may be rotated together with the rotation shaft 2410. For example, at least one protrusion (e.g., the protrusions 2420 and 2430 of FIG. 24) that may be fitted into the fitting recess (e.g., the fitting recesses 2460 and 2470 of FIG. 24) provided in the pad fixing part 211 may be provided in a vertical direction from the rotation shaft 2410. At least one protrusion 2420 and 2430 provided in the rotation shaft 2410 may be inserted into and fixed to the fitting recesses 2460 and 2470 of the pad fixing part 211.

The rotation of the pad fixing part 211 rotates the first pad 213 fixed to the pad fixing part 211 within a predetermined range. This may stably hold the first surface 21 of the electronic device 2 to be fixed by rotating the first pad 213 at a predetermined angle. In an embodiment, the first surface 21 may have, e.g., a slight inclination angle rather than forming a precisely horizontal plane. In this case, the pad fixing part 211 may be rotated at a required angle around the rotation shaft 2410, so that the first pad 213 may be seated parallel to the first surface 21 of the electronic device 2.

As described above, by allowing the pad fixing part 211 to rotate within a predetermined angular range by the rotation shaft 2410, it is possible to reduce the possibility that the first surface 21 of the mounted electronic device 2 is damaged by the first pad 213.

For example, the second clip member 220 may include a second pad 223 at a portion opposite to a handle part on which an external force is applied for the purpose of rotation. The second pad 223 may be disposed in a direction facing the first clip member 210. The second pad 223 may fix a second surface (e.g., the lower surface (e.g., the second surface 23 of FIG. 10)) of the electronic device 2, which is a waterproofing test target. The second pad 223 may be, e.g., formed of urethane. Although not illustrated, the second pad 223 may be mounted on the second clip member 220 using a pad fixing part. The pad fixing part may include, e.g., a guide that may be inserted near the edge of the second pad 223 to be mounted or detached. The second pad 223 may be disposed to face the first pad 213 included in the first clip member 210.

According to an example, the basic type clip device 20 may include a sealing assembly in a length direction on the inner side where the first clip member 210 and the second clip member 220 face each other. For example, the sealing assembly may include a structure capable of sealing the air vent holes (e.g., the first air vent holes 2401, 2411, 2421, and 2431 of FIGS. 24A to 24D) of the electronic device 2 that is held and fixed by the first clip member 210 and the second clip member 220. In another example, the sealing assembly may include a first sealing pad 250, a first pressing prevention guide part 260, a first position adjustment part 261 and 263, or a second position adjustment part 280. One end of the hose 240 may be connected to one side (e.g., the end in the −z direction) of the first sealing pad 250. The other end of the hose 240 may be fitted into the hose fastening hole (e.g., 162 of FIG. 2) of the air adjustment part (e.g., the air adjustment part 180 of FIG. 2) included in the main body 10.

The first sealing pad 250 may be coupled by penetrating the first pressing prevention guide part 260 in the z-axis direction. The first sealing pad 250 may provide a predetermined degree of contraction in response to pressing. The first sealing pad 250 may be formed of, e.g., a rubber material. In an embodiment, the first pressing prevention guide part 260 may prevent damage due to pressing that may occur when the first sealing pad 250 seals the air vent holes 2401, 2411, 2421, and 2431 of the electronic device 2. To this end, it may be preferable that the free end of the first sealing pad 250 including the nozzle 251 for discharging and/or suctioning air does not protrude more than a threshold level in the +z axis direction from the surface of the first pressing prevention guide part 260. The nozzle 251 may be formed substantially near the center of the surface of the first sealing pad 250 to be sealed with the electronic device 2. When the electronic device 2 is mounted on the basic type clip device 20, the nozzle 251 of the first sealing pad 250 may contact the air vent holes 2401, 2411, 2421, and 2431 of the electronic device 2 to provide sealing for preventing air leakage to the outside.

The first position adjustment parts 261 and 263 included in the basic type clip device 20 may adjust the position of the first sealing pad 250 on the y-axis. For example, the first position adjustment parts 261 and 263 may move the first sealing pad 250 in the +y direction in response to clockwise rotation. For example, the first position adjustment parts 261 and 263 may move the first sealing pad 250 in the −y direction in response to counterclockwise rotation. The user may adjust the first position adjustment parts 261 and 263 to adjust the height so that the first sealing pad 250 faces the air vent holes 2401, 2411, 2421, and 2431 of the electronic device 2 on the z-axis.

The second position adjustment part 280 included in the basic type clip device 20 may adjust the position of the first sealing pad 250 on the z-axis. For example, the second position adjustment part 280 may move the second sealing pad 250 in the +z direction in response to rotating in the forward direction of screw progress. For example, the second position adjustment part 280 may move the first sealing pad 250 in the −z direction in response to rotating in the reverse direction of the screw progress. In an embodiment, the user may adjust the second position adjustment part 280 to adjust the degree of pressing of the first sealing pad 250 due to sealing with the air vent holes 2401, 2411, 2421, and 2431 of the electronic device 2 on the z-axis.

According to an embodiment, the first clip member 210 may include a first opening 290. The first opening 290 may be formed to identify the sealing state of the basic type clip device 20 and the electronic device 2 when viewed from the top to the bottom (+x direction). For example, the first opening 290 may be formed to have a predetermined area on the −x axis with respect to a position where the air vent holes 2401, 2411, 2421, and 2431 of the electronic device 2 and the first sealing pad 250 are sealed. The user may adjust the second position adjustment part 280 while observing the degree to which the air vent holes 2401, 2411, 2421, and 2431 of the electronic device 2 and the first sealing pad 250 are sealed through the first opening 290.

According to another embodiment, the second clip member 220 may include a second opening. The second opening may be formed to identify the sealing state of the basic type clip device 20 and the electronic device 2 when viewed from the bottom to the top (−x direction). For example, the second opening may be formed to have a predetermined area on the +x axis with respect to a position where the air vent holes 2401, 2411, 2421, and 2431 of the electronic device 2 and the first sealing pad 250 are sealed. The user may adjust the second position adjustment part 280 while observing the degree to which the air vent holes 2401, 2411, 2421, and 2431 of the electronic device 2 and the first sealing pad 250 are sealed through the second opening.

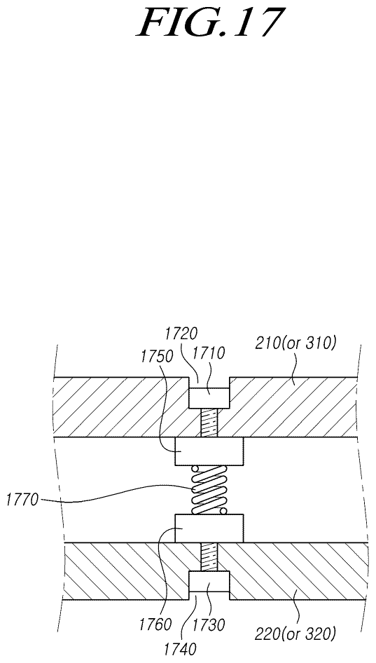

The basic type clip device 20 may include an elastic assembly S3, S4 (e.g., the elastic assembly 1700 of FIG. 17) capable of adjusting a pressing force applied to the electronic device 2 due to a clip structure when fastening with the electronic device 2. The elastic assembly S3, S4 may provide a restoring force (e.g., an elastic force) for returning to a closed state, which is the original state, from a state in which the basic type clip device 20 having a clip structure is opened by external force. The restoring force may act as, e.g., a force for fixing the electronic device 2. In an embodiment, the elastic assembly S3, S4 may be provided, e.g., near the handle of the first clip member 210 included in the basic type clip device 20 and near the handle of the second clip member 220. The elastic assembly S3, S4 may have a structure in which it is easy to replace it with an elastic material (e.g., a spring) capable of providing an appropriate restoring force in consideration of the strength or material of the vicinity where the biting force acts by the basic type clip device 20.

FIG. 10 is a rear perspective view illustrating a basic type clip device (e.g., the basic type clip device 20 of FIG. 1) included in a waterproofing test device (e.g., the waterproofing test device 1 of FIG. 1) according to an embodiment of the disclosure.

FIG. 11 is a state diagram in which a basic type clip device (e.g., the basic type clip device 20 of FIG. 1) included in a waterproofing test device (e.g., the waterproofing test device 1 of FIG. 1) is mounted on an electronic device to be tested according to an embodiment of the disclosure.

Referring to FIG. 10 or 11, the electronic device 2 may be fixed by pressing of the first clip member 210 and the second clip member 220 included in the basic type clip device 20. In the electronic device 2, the air vent holes (e.g., the first air vent holes 2401, 2411, 2421, and 2431 of FIGS. 24A to 24D) may be aligned on the same axis (e.g., z axis) as the first sealing pad 250 included in the basic type clip device 20. The user may align the position of the first sealing pad 250 with respect to the air vent holes 2401, 2411, 2421, and 2431 of the electronic device 2 by manipulating the first position adjustment parts 261 and 263 included in the basic type clip device 20. One end of the hose 240 may be connected to one side (e.g., the end in the −z direction) of the first sealing pad 250. The other end of the hose 240 may be fitted into the hose fastening hole (e.g., 162 of FIG. 2) of the air adjustment part (e.g., the air adjustment part 180 of FIG. 2) included in the main body 10.

The air vent holes 2401, 2411, 2421, and 2431 of the electronic device 2 may be sealed by the first sealing pad 250 included in the basic type clip device 20. In an embodiment, the user may move the position of the first sealing pad 250 on the z-axis by manipulating the second position adjustment part 280 included in the basic type clip device 20. For example, the second position adjustment part 280 may move the first sealing pad 250 in the +z direction in response to rotating in the forward direction of screw progress. For example, the second position adjustment part 280 may move the first sealing pad 250 in the −z direction in response to rotating in the reverse direction of the screw progress. The user may adjust the second position adjustment part 280 to adjust the degree of pressing of the first sealing pad 250 due to sealing with the air vent holes 2401, 2411, 2421, and 2431 of the electronic device 2 on the z-axis.

The first opening 290 included in the first clip member 210 allows the user to adjust the second position adjustment part 280 while observing the degree to which the air vent holes 2401, 2411, 2421, and 2431 of the electronic device 2 and the first sealing pad 250 are sealed.

The first sealing pad 250 may be formed of a rubber material capable of contracting to a predetermined degree in response to pressing. Even when the second position adjustment part 280 is excessively adjusted by the user, damage due to pressing by the first pressing prevention guide part 260 may be prevented.

FIG. 12 is a plan view illustrating a common type clip device (e.g., the common type clip device 30 of FIG. 1) included in a waterproofing test device (e.g., the waterproofing test device 1 of FIG. 1) according to an embodiment of the disclosure.

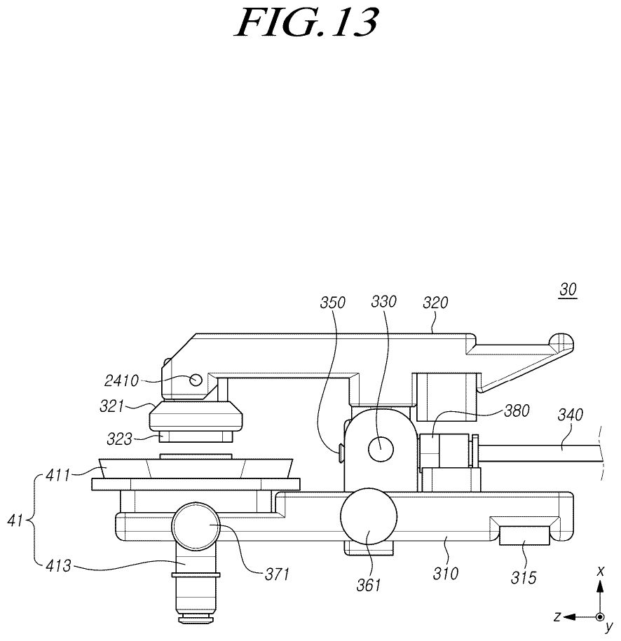

FIG. 13 is a front view illustrating a common type clip device (e.g., the common type clip device 30 of FIG. 1) included in a waterproofing test device (e.g., the waterproofing test device 1 of FIG. 1) according to an embodiment of the disclosure.

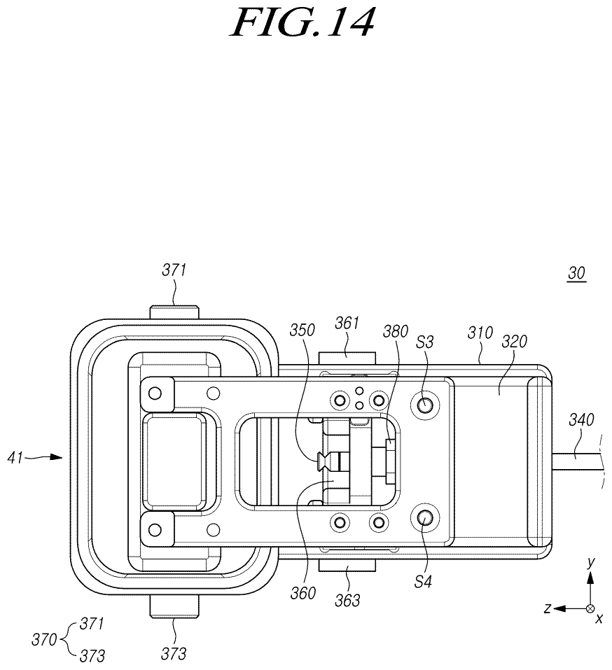

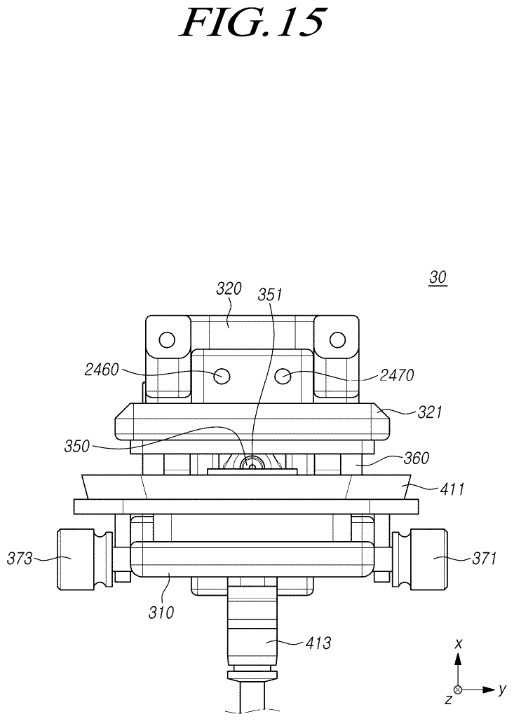

FIG. 14 is a bottom view illustrating a common type clip device (e.g., the common type clip device 30 of FIG. 1) included in a waterproofing test device (e.g., the waterproofing test device 1 of FIG. 1) according to an embodiment of the disclosure.

FIG. 15 is a left side view illustrating a common type clip device (e.g., the common type clip device 30 of FIG. 1) included in a waterproofing test device (e.g., the waterproofing test device 1 of FIG. 1) according to an embodiment of the disclosure.

Referring to FIGS. 12 to 15, the common type clip device 30 may include a third clip member 310, a fourth clip member 320, or a second rotation shaft 330 for rotatably connecting the third clip member 310 and the fourth clip member 320. The third clip member 310 may be an upper clip member. The fourth clip member 320 may be a lower clip member. The second rotation shaft 330 may be positioned substantially near the middle or at a point between the middle and the handle side where the external force acts in the third clip member 310 and/or the fourth clip member 320.

The third clip member 310 may have two third fastening protrusions formed substantially near the middle in the length direction. The third fastening protrusions may be formed to face two opposite side surfaces near the middle of the third clip member 310. The third fastening protrusion may include a third fastening hole at substantially the same height. The third fastening hole may be used for coupling with the fourth clip member 320 by the second rotation shaft 330.

According to an embodiment, the fourth clip member 320 may have two fourth fastening protrusions formed substantially near the middle in the length direction. The fourth fastening protrusions may be formed to face two opposite side surfaces near the middle of the third clip member 310. The fourth fastening protrusion may include a fourth fastening hole at substantially the same height. The fourth fastening hole may be used for coupling with the third clip member 310 by the second rotation shaft 330.

For example, the third fastening protrusion included in the third clip member 310 may be fitted outside the fourth fastening protrusion included in the fourth clip member 320. For example, the third fastening protrusion included in the third clip member 310 may be fitted inside the fourth fastening protrusion included in the fourth clip member 320. In this case, the third fastening hole provided in the third fastening protrusion and the fourth fastening hole provided in the fourth fastening protrusion may be aligned in a straight line. This will allow the third clip member 310 and the fourth clip member 320 to rotate with respect to the second rotation shaft 330 as the second rotation shaft 330 passes through the third fastening hole and the fourth fastening hole.

When the handle near the third clip member 310 and/or the handle near the fourth clip member 320 is pressed by an external force, the third clip member 310 and/or the fourth clip member 320 may rotate around the second rotation shaft 330. In this case, the rotation around the second rotation shaft 330 may cause a movement, such as the opening of the clip, of the opposite part of the handle. For example, the vicinity of the handle of the third clip member 310 may rotate in the +x direction around the second rotation axis 330, and the vicinity of the handle of the fourth clip member 320 may rotate in the −x direction around the second rotation axis 330.

When the external force is removed, the third clip member 310 and/or the fourth clip member 320 may rotate around the second shaft 330. In this case, rotation around the second rotation shaft 330 may cause a movement, such as closing of the clip, of the opposite part of the handle. The vicinity of the handle of the third clip member 310 may rotate in the −x direction around the second rotation shaft 330, and the vicinity of the handle of the fourth clip member 320 may rotate in the +x direction around the second rotation shaft 330.

As an example, the third clip member 310 may include a dedicated air pad coupling portion, where the dedicated air pad 41, 43 may be mounted, at a portion opposite to the handle part on which an external force is applied for the purpose of rotation. The drawings illustrate an example in which the first dedicated air pad 41 is mounted, but the second dedicated air pad 43 may be mounted. In the following description, it is described that the first dedicated air pad 41 is mounted for convenience of description, but the second dedicated air pad 43 may also be described in the same manner. In an embodiment, the dedicated air pad 41, 43 may serve as a third pad of the common type clip device 30. The dedicated air pad coupling part may include a through hole 393 provided near the end of the third clip member 310. A flow path tube 413 included in the dedicated air pad 41 may be fitted into the through hole 393 in the −x direction. For example, the flow path tube 413 may be inserted into the through hole 393 until the dedicated sealing pad 411 included in the dedicated air pad 41 tightly contacts the third clip member 310. The movement of the flow path tube 413 inserted into the through hole 393 may be limited by at least one fixing pin.

For example, the dedicated air pad coupling part may include fixing pins 370 (i.e., first and second fixing pins 371 and 373) penetrating a side surface of the through hole 393. End portions of the first and second fixing pins 371 and 373 may tightly contact an outer surface of the flow path tube 413 to fix the flow path tube 413 so as not to move any more. The end portions of the first and second fixing pins 371 and 373 may be fitted into the recesses having a predetermined depth in the outer surface of the flow path tube 413. As the first and second fixing pins 371 and 373 are fitted into the recesses, the flow path tube 413 may be more firmly fixed. The first fixing pin 371 may have a structure in which an end portion of the first fixing pin 371 proceeds toward the flow path tube 413 in response to clockwise or counterclockwise rotation. In response to rotation in the opposite direction, the first fixing pin 371 may have a structure in which an end portion thereof may proceed in a direction opposite to the flow path tube 413. In an embodiment, the second fixing pin 373 may have a structure in which an end thereof may proceed toward the flow path tube 413 in response to clockwise or counterclockwise rotation. In response to rotation in the opposite direction, the second fixing pin 373 may have a structure in which an end portion thereof may proceed in a direction opposite to the flow path tube 413.

For example, the dedicated air pad 41 coupled to the dedicated air pad coupling part may be disposed in a direction facing the fourth clip member 320. The dedicated air pad 41 may fix a second surface (e.g., the lower surface (e.g., the second surface 23 of FIG. 10)) of an electronic device (e.g., the electronic device 2 of FIG. 10), which is a waterproofing test target. The dedicated air pad 41 may be, e.g., formed of a urethane material.

The fourth clip member 320 may include a fourth pad 323 at a portion opposite to a handle part on which an external force is applied for the purpose of rotation. The fourth pad 323 may be disposed in a direction facing the third clip member 310. The fourth pad 323 may fix a first surface (e.g., the upper surface (e.g., the first surface 21 of FIG. 10)) of the electronic device 2, which is a waterproofing test target. The fourth pad 323 may be, e.g., formed of a urethane material. The fourth pad 323 may be mounted on the fourth clip member 320 using a pad fixing part 321. The pad fixing part 321 may include, e.g., a guide that may be inserted near the edge of the fourth pad 323 to be mounted or detached. The fourth pad 323 may be disposed to face the dedicated air pad 41 corresponding to the third pad fastened to the third clip member 310.

The pad fixing part 321 may be fitted into the fourth clip member 320 by a shaft that operates as a rotation axis (e.g., the rotation axis 2410 of FIG. 24) on the y axis. The pad fixing part 321 may rotate in a predetermined direction (e.g., in direction c or direction d of FIG. 24) by the rotation shaft 2410. The pad fixing part 321 may rotate around the rotation shaft 2410, e.g., when the rotation shaft 2410 is fixed by fitting into a fitting recess (e.g., the fitting recesses 2440 and 2450 of FIG. 24) provided in the fourth clip member 320. For example, when the rotation shaft 2410 is fitted into the fourth clip member 320 to be rotatable, the pad fixing part 321 may be rotated together with the rotation shaft 2410. For example, at least one protrusion (e.g., the protrusions 2420 and 2430 of FIG. 24) that may be fitted into the fitting recess (e.g., the fitting recesses 2460 and 2470 of FIG. 24) provided in the pad fixing part 321 may be provided in a vertical direction from the rotation shaft 2410. At least one protrusion 2420 and 2430 provided in the rotation shaft 2410 may be inserted into and fixed to the fitting recesses 2460 and 2470 of the pad fixing part 321.

In an embodiment, the rotation of the pad fixing part 321 rotates the fourth pad 323 fixed to the pad fixing part 321 within a predetermined range. This may stably hold one surface of the electronic device 2 to be fixed by rotating the fourth pad 323 at a predetermined angle. The one surface may have, e.g., a slight inclination angle rather than forming a precisely horizontal plane. In this case, the pad fixing part 321 may be rotated at a required angle around the rotation shaft 2410, so that the fourth pad 323 may be seated parallel to the one surface of the electronic device 2.

As described above, by allowing the pad fixing part 321 to rotate within a predetermined angular range by the rotation shaft 2410, it is possible to reduce the possibility that the one surface of the mounted electronic device 2 is damaged by the first pad 323.

According to an example, the common type clip device 30 may include a sealing assembly in a length direction on the inner side where the third clip member 310 and the fourth clip member 320 face each other. For example, the sealing assembly may include a structure capable of sealing the air vent holes (e.g., the second air vent holes 2413 and 2433 of FIG. 24B or 24D) of the electronic device 2 that is held and fixed by the third clip member 310 and the fourth clip member 320. For example, the sealing assembly may include a second sealing pad 350, a second pressing prevention guide part 360, a first position adjustment part 361 and 363, or a second position adjustment part 380. One end of the hose 340 may be connected to one side (e.g., the end in the −z direction) of the second sealing pad 350. The other end of the hose 340 may be fitted into the hose fastening hole (e.g., 161 of FIG. 2) of the air adjustment part (e.g., the air adjustment part 180 of FIG. 2) included in the main body 10.

The second sealing pad 350 may be coupled by penetrating the second pressing prevention guide part 360 in the z-axis direction. The second sealing pad 350 may provide a predetermined degree of contraction in response to pressing. The second sealing pad 350 may be formed of, e.g., a rubber material. In an embodiment, the second pressing prevention guide part 360 may prevent damage due to pressing that may occur when the second sealing pad 350 seals the air vent holes 2413 and 2433 of the electronic device 2. To this end, it may be preferable that the free end of the second sealing pad 350 including the nozzle 351 for discharging and/or suctioning air does not protrude more than a threshold level in the +z axis direction from the surface of the second pressing prevention guide part 360. The nozzle 351 may be formed substantially near the center of the surface of the second sealing pad 350 to be sealed with the electronic device 2. When the electronic device 2 is mounted on the common type clip device 30, the nozzle 351 of the second sealing pad 350 may contact the air vent holes 2413 and 2433 of the electronic device 2 to provide sealing for preventing air leakage to the outside.

The first position adjustment parts 361 and 363 included in the common type clip device 30 may adjust the position of the second sealing pad 350 on the y-axis. For example, the first position adjustment parts 361 and 363 may move the second sealing pad 350 in the +y direction in response to clockwise rotation. For example, the first position adjustment parts 361 and 363 may move the second sealing pad 350 in the −y direction in response to counterclockwise rotation. The user may adjust the first position adjustment parts 361 and 363 to adjust the height so that the second sealing pad 350 faces the air vent holes 2413 and 2433 of the electronic device 2 on the z-axis.

The second position adjustment part 380 included in the common type clip device 30 may adjust the position of the second sealing pad 350 on the z-axis. For example, the second position adjustment part 380 may move the second sealing pad 350 in the +z direction in response to rotating in the forward direction of screw progress. For example, the second position adjustment part 380 may move the second sealing pad 350 in the −z direction in response to rotating in the reverse direction of the screw progress. In an embodiment, the user may adjust the second position adjustment part 380 to adjust the degree of pressing of the second sealing pad 350 due to sealing with the air vent holes 2413 and 2433 of the electronic device 2 on the z-axis.

According to an embodiment, the third clip member 310 may include a third opening 390. The third opening 390 may be formed to identify the sealing state of the common type clip device 30 and the electronic device 2 when viewed from the top to the bottom (+x direction). For example, the third opening 390 may be formed to have a predetermined area on the −x axis with respect to a position where the air vent holes 2413 and 2433 of the electronic device 2 and the second sealing pad 350 are sealed. The user may adjust the second position adjustment part 380 while observing the degree to which the air vent holes 2413 and 2433 of the electronic device 2 and the second sealing pad 350 are sealed through the third opening 390.

According to an embodiment, the fourth clip member 320 may include a fourth opening. The fourth opening may be formed to identify the sealing state of the common type clip device 30 and the electronic device 2 when viewed from the bottom to the top (−x direction). For example, the fourth opening may be formed to have a predetermined area on the +x axis with respect to a position where the air vent holes 2413 and 2433 of the electronic device 2 and the second sealing pad 350 are sealed. The user may adjust the second position adjustment part 280 while observing the degree to which the air vent holes 2413 and 2433 of the electronic device 4 and the second sealing pad 350 are sealed through the second opening.

The common type clip device 30 may include an elastic assembly S1, S2 (e.g., the elastic assembly 1700 of FIG. 17) capable of adjusting a pressing force applied to the electronic device 2 due to a clip structure when fastening with the electronic device 2. The elastic assembly S1, S2 may provide a restoring force (e.g., an elastic force) for returning to a closed state, which is the original state, from a state in which the common type clip device 30 having a clip structure is opened by external force. The restoring force may act as, e.g., a force for fixing the electronic device 2. In an embodiment, the elastic assembly S1, S2 may be provided, e.g., near the handle of the third clip member 310 included in the common type clip device 30 and near the handle of the fourth clip member 320. The elastic assembly S1, S2 may have a structure in which it is easy to replace it with an elastic material (e.g., a spring) capable of providing an appropriate restoring force in consideration of the strength or material of the vicinity where the biting force acts by the common type clip device 30.

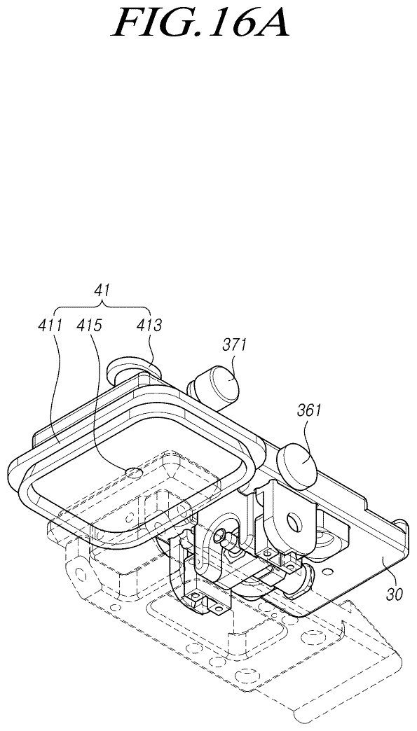

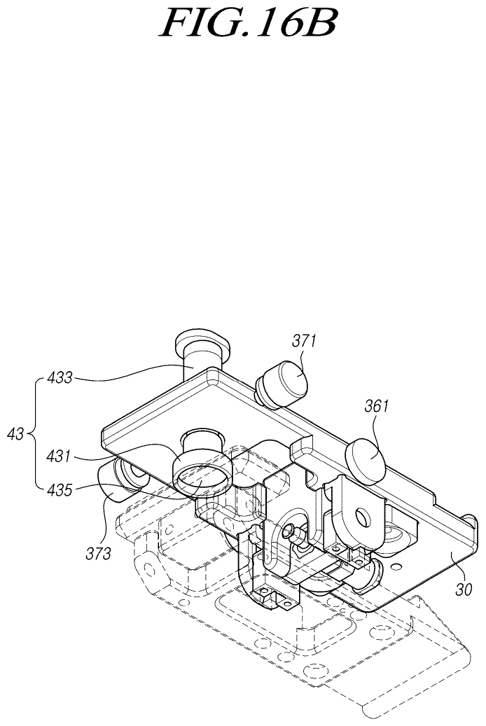

FIG. 16A is a see-through perspective view illustrating that a flat dedicated pad (e.g., the first dedicated air pad 41 of FIG. 1) is attached to a common type clip device (e.g., the common type clip device 30 of FIG. 1) included in a waterproofing test device (e.g., the waterproofing test device 1 of FIG. 1) according to an embodiment of the disclosure.

Referring to FIG. 16A, the first dedicated air pad 41 mounted on the common type clip device 30 may be a flat plate type. Accordingly, the first dedicated air pad 41 may be referred to as a flat plate type dedicated pad.

The first dedicated air pad 41 may be mounted on the common clip device 30 to perform a waterproofing test on an electronic device (e.g., the electronic device 2 of FIG. 10) having air vent holes (e.g., the second air vent hole 2423 of FIG. 24c) widely disposed on an upper surface (e.g., the first surface 21 of FIG. 10) or a lower surface (e.g., the second surface 43 of FIG. 10) thereof. In the first dedicated air pad 41, a planar type dedicated sealing pad 411 may be disposed in a first direction toward the electronic device 2 to perform a waterproofing test. The dedicated sealing pad 411 may be provided with a nozzle 415 substantially near the center thereof. The nozzle 415 may pass through the dedicated sealing pad 411. The first dedicated air pad 41 may include a flow path tube 413 extending by a predetermined length in a second direction from the nozzle 415 passing through the dedicated sealing pad 411. The second direction may be a direction opposite to the first direction. The flow path tube 413 may include a substantially circular inner flow path. In the flow path tube 413, air introduced through an opening at one end may be discharged through an opening at the opposite end.

For example, when air is discharged through the nozzle 415 of the dedicated sealing pad 411, a flow path from the opening of the free end which is the end in the second direction to the opening connected to the nozzle 415, which is the end in the first direction, may be formed in the flow path tube 413. In this case, the air discharged through the nozzle 415 of the dedicated sealing pad 411 for waterproofing test may be injected into the electronic device 2 through the air vent hole of the electronic device 2 to increase the internal pressure of the electronic device 2.

When air is discharged from the flow path tube 413 through the opening of the free end which is the end in the second direction, a flow path from the opening connected to the nozzle 415, which is the end in the first direction, to the opening of the free end, which is the end in the second direction, may be formed in the flow path tube 413. In this case, the internal pressure of the electronic device 2 may be reduced by suctioning the air inside the electronic device 2 through the nozzle 415 of the dedicated sealing pad 411 sealed in the air vent hole of the electronic device 2.

According to an example, the common type clip device 30 may have a through hole (e.g., the through hole 393 of FIG. 12) near the end of the upper clip member (e.g., the third clip member 310 of FIG. 12) that is held on the upper surface (e.g., the first surface 21 of FIG. 10) of the electronic device 2. The flow path tube 413 included in the first dedicated air pad 41 may be fitted into the through hole 393 in the second direction. For example, the flow path tube 413 may be fitted into the through hole 393 until the dedicated sealing pad 411 included in the first dedicated air pad 41 tightly contacts the upper clip member 310. In an embodiment, the movement of the flow path tube 413 fitted into the through hole 393 may be limited by at least one fixing pin. For example, end portions of the first and second fixing pins 371 and 373 penetrating the side surface of the through hole 393 may tightly contact the outer surface of the flow path tube 413 to fix the flow path tube 413 so as not to move any longer. A recess may be formed at the position where the end portion of the first fixing pin 371 and/or the second fixing pin 373 is to tightly contact on the outer surface of the flow path tube 413 to allow the end portion to be inserted to a certain depth. The recess may allow the flow path tube 413 to be more firmly fixed by the first and second fixing pins 371 and 373. The first fixing pin 371 may be designed in a structure in which an end portion thereof may proceed toward the flow path tube 413 in response to clockwise or counterclockwise rotation. The second fixing pin 373 may be designed in a structure in which an end portion thereof may proceed toward the flow path tube 413 in response to clockwise or counterclockwise rotation.

FIG. 16B is a see-through perspective view illustrating that a cylindrical dedicated pad (e.g., the second dedicated air pad 43 of FIG. 1) is attached to a common type clip device (e.g., the common type clip device 30 of FIG. 1) included in a waterproofing test device (e.g., the waterproofing test device 1 of FIG. 1) according to an embodiment of the disclosure.

Referring to FIG. 16B, the second dedicated air pad 43 mounted on the common type clip device 30 may be of a cylindrical type. Accordingly, the second dedicated air pad 43 may be referred to as a cylindrical dedicated pad.

According to an example, the second dedicated air pad 43 may be mounted on the common clip device 30 to perform a waterproofing test on the electronic device (e.g., the second air vent hole 2403 of FIG. 24A or the second air vent hole 2433 of FIG. 24D) having one air vent hole (e.g., the electronic device 2 of FIG. 10) disposed on the upper surface (e.g., the first surface 21 of FIG. 10) or the lower surface (e.g., the second air vent hole 43 of FIG. 10) thereof. In the first dedicated air pad 43, a cylindrical type dedicated sealing pad 431 may be disposed in a first direction toward the electronic device 2 to perform a waterproofing test. The dedicated sealing pad 431 may be provided with a nozzle 435 substantially near the center thereof. The nozzle 435 may pass through the dedicated sealing pad 431. In an embodiment, the second dedicated air pad 43 may include a flow path tube 433 extending by a predetermined length in a second direction from the nozzle 435 passing through the dedicated sealing pad 431. The second direction may be a direction opposite to the first direction. The flow path tube 433 may include a substantially circular inner flow path. In the flow path tube 433, air introduced through an opening at one end may be discharged through an opening at the opposite end.

For example, when air is discharged through the nozzle 435 of the dedicated sealing pad 431, a flow path from the opening of the free end which is the end in the second direction to the opening connected to the nozzle 435, which is the end in the first direction, may be formed in the flow path tube 433. In this case, the air discharged through the nozzle 435 of the dedicated sealing pad 431 for waterproofing test may be injected into the electronic device 2 through the air vent hole of the electronic device 2 to increase the internal pressure of the electronic device 2.

For example, when air is discharged from the flow path tube 433 through the opening of the free end which is the end in the second direction, a flow path from the opening connected to the nozzle 435, which is the end in the first direction, to the opening of the free end, which is the end in the second direction, may be formed in the flow path tube 433. In this case, the internal pressure of the electronic device 2 may be reduced by suctioning the air inside the electronic device 2 through the nozzle 435 of the dedicated sealing pad 431 sealed in the air vent hole of the electronic device 2.

The common type clip device 30 may have a through hole (e.g., the through hole 393 of FIG. 12) near the end of the upper clip member (e.g., the third clip member 310 of FIG. 12) that is held on the upper surface (e.g., the first surface 21 of FIG. 10) of the electronic device 2. The flow path tube 433 included in the second dedicated air pad 43 may be fitted into the through hole 393 in the second direction. For example, the flow path tube 433 may be fitted into the through hole 393 until the dedicated sealing pad 431 included in the second dedicated air pad 43 tightly contacts the upper clip member 310. The movement of the flow path tube 433 fitted into the through hole 393 may be limited by at least one fixing pin. For example, end portions of the first and second fixing pins 371 and 373 penetrating the side surface of the through hole 393 may tightly contact the outer surface of the flow path tube 433 to fix the flow path tube 433 so as not to move any longer. A recess may be formed at the position where the end portion of the first fixing pin 371 and/or the second fixing pin 373 is to tightly contact on the outer surface of the flow path tube 433 to allow the end portion to be inserted to a certain depth. The recess may allow the flow path tube 433 to be more firmly fixed by the first and second fixing pins 371 and 373. The first fixing pin 371 may be designed in a structure in which an end portion thereof may proceed toward the flow path tube 433 in response to clockwise or counterclockwise rotation. The second fixing pin 373 may be designed in a structure in which an end portion thereof may proceed toward the flow path tube 433 in response to clockwise or counterclockwise rotation.

FIG. 17 is a view illustrating a structure of an elastic assembly that provides elastic force for fixing a test target (e.g., the electronic device 2 of FIG. 10 or 11) in a clip device (e.g., the basic clip device 20 or the common clip device 30 of FIG. 1) included in a waterproofing test device (e.g., the waterproofing test device 1 of FIG. 1) according to an embodiment of the disclosure.

Referring to FIG. 17, the elastic assembly 1700 may provide a restoring force (e.g., an elastic force) for returning to a closed state, which is the original state, from a state in which the clip device 20, 30 having a clip structure is opened by external force. For example, the elastic assembly 1700 may be provided near the handle of the first clip member 210 or 310 (or upper clip member) included in the clip device 20, 30 and near the handle of the second clip member 220 or 320 (or lower clip member).

The clip device 20, 30 may use a restoring force in the elastic assembly 1700 as energy to fix the electronic device 2 by mechanical fastening by holding the first surface (e.g., the upper surface 21 of FIG. 10) and the second surface (e.g., the lower surface 23 of FIG. 10) of the electronic device 2 for waterproofing test. The restoring force may be generated by a mechanical element used in the elastic assembly 1700. If the spring is used as the mechanical element, the restoring force in the elastic assembly 1700 may correspond to the elastic force corresponding to a force to return to its original state from the state in which the spring is pressed. In the disclosure, the term ‘elastic force’ may replace the term ‘restoring force.’ The elastic force may be determined, e.g., by a force that the mechanical element in the elastic assembly 1700 may accumulate or by the number of mechanical elements included in the elastic assembly 1700.

As the elastic force increases, the force applied to the electronic device 2 by the clip device 20, 30 may increase, and as the elastic force decreases, the force applied to the electronic device 2 by the clip device 20, 30 may decrease. When the elastic force is too large, a negative effect (damage) may be had on the electronic device 2. Therefore, it is necessary to optimize the elastic force by the mechanical element provided in the elastic assembly 1700 in consideration of the possible influence on the electronic device 2 that is mechanically fastened with the clip device 20, 30.

The elastic force of the spring 1770 mounted on the elastic assembly 1700 may determine the pressure at which the clip device 20, 30 vertically presses for mechanical fastening with the electronic device 2. Therefore, an elastic spring 1770 may be used in the elastic assembly 1700 to provide a pressure suitable for the electronic device 2 to which the clip device 20, 30 will mechanically fasten. In other words, the spring 1770 mounted on the elastic assembly 1700 may be replaced for the purpose of changing the elastic force. To this end, the elastic assembly 1700 may be designed in a structure in which the mounted spring 1770 is removed and a new spring is easily mounted. For example, the elastic force that may be provided by the spring 1770 may be 6.6 kgf. The provision of an elastic force of 6.6 kgf by the spring 1770 is an example defined in the JIG specification in response to a specific circumstance, and a different value of elastic force may be applied. For example, the elastic force of the spring may be determined in consideration of the material or strength of the portion to be pressed by the clip device 20, 30 in the electronic device 2. For example, if the portion to be pressed by the clip device 20, 30 is formed of a hard material, a spring that provides a relatively high elastic force may be mounted on the elastic assembly 1700. For example, if the portion to be pressed by the clip device 20, 30 is formed of a material with a high risk of damage, such as a display, a spring that provides a relatively low elastic force may be mounted on the elastic assembly 1700.

In an example, the elastic assembly 1700 may include a first fixing screw 1710, a first screw hole 1720, a second fixing screw 1730, a second screw hole 1740, a first covering film 1750, a second covering film 1760, or a spring 1770. The first screw hole 1720 may be formed by penetrating the vicinity of the handle of the first clip member 210 or 310 of the clip device 20, 30. The second screw hole 1740 may be formed by penetrating the vicinity of the handle of the second clip member 220 or 320 of the clip device 20, 30.

According to an embodiment, the first fixing screw 1710 may be inserted into and fastened to the first screw hole 1720. When the first fixing screw 1710 is fastened to the first screw hole 1720, the first fixing screw 1710 may be immersed in the first screw hole 1720 so that the screw head does not protrude to the outside. The end of the first fixing screw 1710 opposite to the screw head may contact the first surface (e.g., the upper plate) of the first covering film 1750. The first fixing screw 1710 may press the first covering film 1750 by passing through the first screw hole 1720 and proceeding in a fastening direction.

According to an embodiment, the second fixing screw 1730 may be inserted into and fastened to the second screw hole 1740. When the second fixing screw 1730 is fastened to the second screw hole 1740, the second fixing screw 1730 may be immersed in the second screw hole 1740 so that the screw head does not protrude to the outside. In an embodiment, the end of the second fixing screw 1730 opposite to the screw head may contact the second surface (e.g., the lower plate) of the second covering film 1770. The second fixing screw 1730 may press the second covering film 1760 by passing through the second screw hole 1740 and proceeding in a fastening direction.

According to an embodiment, the spring 1770 may be fitted between the first covering film 1750 and the second covering film 1760. For example, one end of the spring 1770 may be fixed to the second surface (e.g., the lower plate) of the first covering film 1750, and the other end may be fixed to the first surface (e.g., the upper plate) of the second covering film 1760. A protrusion over which one side of the spring 1770 is inserted and fixed may be formed on the second surface (e.g., the lower plate) of the first covering film 1750. A protrusion over which the other side of the spring 1770 is inserted and fixed may be formed on the first surface (e.g., the upper plate) of the second covering film 1760. In this case, the spring 1770 may be compressed by the pressing of the first covering film 1750 and/or the pressing of the second covering film 1760. In an embodiment, the spring 1770 may have an elastic force corresponding to the degree of pressing of the first covering film 1750 and/or the second covering film 1760.

In the elastic assembly 1700 having the above-described structure, the force pressing the spring 1770 may be decreased or removed by operating the first fixing screw 1710 and/or the second fixing screw 1730 in the unfastening direction. When the elastic assembly 1700 reduces or removes the force pressing the spring 1770, the user may easily remove the spring 1770 mounted on the elastic assembly 1700 or mount a new spring.

According to an embodiment, if the spring 1770 is not excessively pressed in the elastic assembly 1700, the user may press and remove the spring 1770 or press and mount a new spring. The state in which the spring 1770 is excessively pressed may be a state in which a force is applied by the first covering film 1750 and/or the second covering film 1760 so that even when the user forcibly presses the spring 1770, it cannot be removed.

Only one elastic assembly 1700 is illustrated in the drawings, but a plurality of elastic assemblies may be provided in the direction of transversing the clip device 20, 30. Each of the plurality of assemblies may have the same structure as illustrated in the drawings. In this case, the combined elastic force by the springs included in the plurality of elastic assemblies may be 6.6 kgf. The provision of an elastic force of 6.6 kgf by the plurality of elastic assemblies is an example defined in the JIG specification corresponding to a specific circumstance, and a different value of elastic force may be applied.

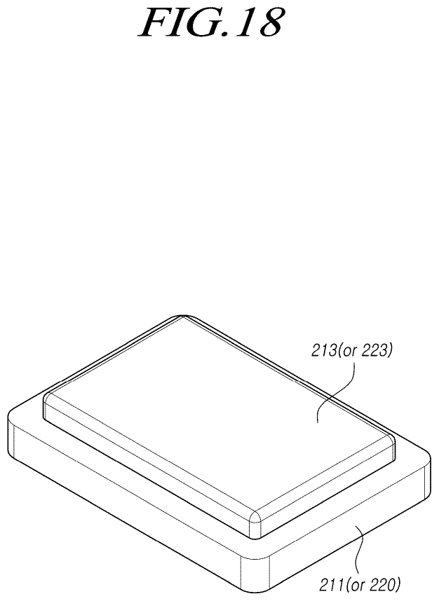

FIG. 18 is a structural view illustrating an anti-slip pad (e.g., the first and second urethane pads 213 and 223 of FIG. 7 or the urethane pad 323 of FIG. 13) provided to fix an electronic device (e.g., the electronic device 2 of FIG. 11) to be tested in a clip device (e.g., the basic type clip device 20 or the common type clip device 30 of FIG. 1) according to an embodiment of the disclosure.

Referring to FIG. 18, one surface of the urethane pad 213 or 223 may be attached to the fixing part 211 or 220 near the clip provided in the clip device 20, 30 for attachment of the electronic device 2. The attachment surface of the urethane pad 213 or 223 exposed to the outside may not be subjected to a surface processing treatment. This may not only increase the contact of the electronic device 2 to the glass surface, but also prevent damage to the display of the electronic device 2.

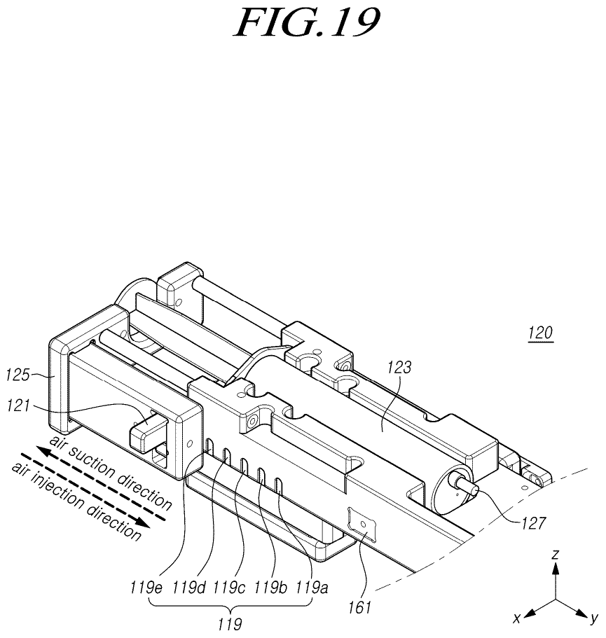

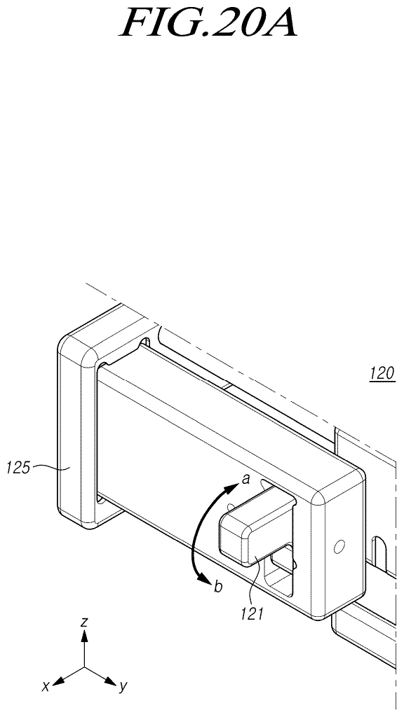

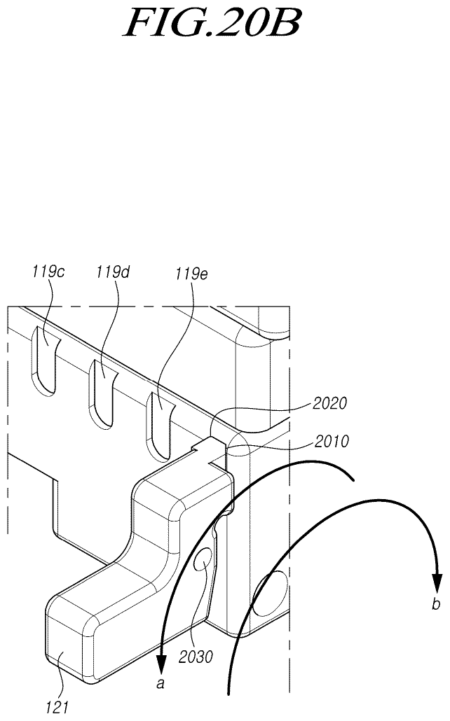

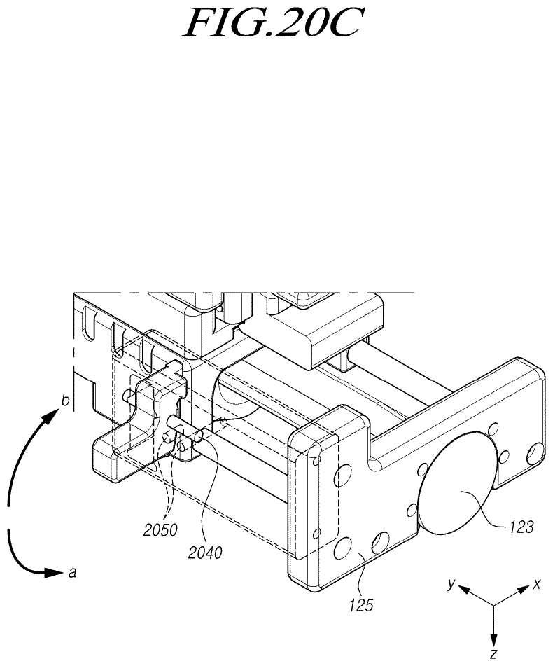

FIG. 19 or 20A, 20B, and 20C are views illustrating an operation example of a pressure adjustment part (e.g., the pressure adjustment part 120 of FIG. 1) for changing an internal pressure of an electronic device (e.g., the electronic device 2 of FIG. 10) to be tested in a waterproofing test device (e.g., the waterproofing test device 1 of FIG. 1) according to various embodiments of the disclosure.

Referring to FIG. 19 or 20A to 20C, the pressure adjustment part 120 may include an adjustment handle part 121, a syringe 123, or a syringe mounting part 125. The adjustment handle part 121 may be integrally formed with the syringe mounting part 125. The syringe 123 may be mounted on the syringe mounting part 125. The syringe mounting part 125 may include, e.g., a syringe mounting frame to which the syringe 123 is fitted and coupled.

In the pressure adjustment part 120, the syringe 123 may be mounted on the syringe mounting part 125, and the syringe 123 may be filled with air by the movement of the adjustment handle part 121 in the air suction direction (e.g., −y direction). The air filling the syringe 123 may be suctioned from the inside of the electronic device (e.g., the electronic device 2 of FIG. 10), which is a waterproofing test target, through a flow path formed by sealing. In this case, the internal pressure of the electronic device 2 may be decreased.

In the pressure adjustment part 120, the syringe 123 is mounted on the syringe mounting part 125, and the air filling the syringe 123 may be discharged to the outside by the movement of the adjustment handle part 121 in the air injection (or discharge) direction (e.g., +y direction). Air discharged from the syringe 123 may be injected into the electronic device 2, which is a waterproofing test target, through a flow path formed by sealing, for example. In this case, the internal pressure of the electronic device 2 may be increased.

The syringe 123 may include a body capable of storing air in the inner housing. The syringe 123 may include an air nozzle 127 for discharging air filling the inner housing or suctioning air to fill the inner housing. The syringe 123 may include a piston configured to adjust a space in which air is to be stored in the inner housing.

The syringe mounting part 125 may have a structure in which the piston of the coupled syringe 123 may move forward (e.g., in the +y direction) or backward (e.g., in the −y direction) by an external force. In another embodiment, the syringe mounting part 125 may include a fixing frame to which the main body of the syringe 123 is to be fixed. The fixing frame may reflect, e.g., the exterior of the main body of the syringe 123. The fixing frame may be open in front and rear directions. The air nozzle 127 of the syringe 123 mounted may face the open front in the fixing frame may face. The open end (e.g., the end in the −y direction) constituting the piston of the syringe 123 mounted may face the open rear in the fixed frame may be directed.

The syringe mounting part 125 may have a sliding structure in which a second member to which the open end of the piston included in the syringe 123 is fixed is moved forward or backward along the first member corresponding to the fixing frame to which the body of the syringe 123 is fixed.

For example, when the second member moves forward along the first member, the air filling the syringe 123 may be discharged through the air nozzle 127. In other words, by forcibly narrowing the inner space of the body filled with air in the syringe 123, some of the air filling the body may be discharged to the air nozzle 127. The air discharged to the nozzle 127 may be injected into the electronic device 2, which is a waterproofing test target, through a flow path formed by sealing. In this case, the internal pressure of the electronic device 2 may be increased.

If a problem arises with the waterproof performance of the electronic device 2, the internal pressure of the electronic device 2 will return to the atmospheric pressure level over time. For example, the amount of change according to the degree to which the internal pressure of the electronic device 2 is reduced is measured and, when the measured amount of change is measured above the threshold level, it may be determined that a problem occurs with the waterproof performance of the electronic device 2.

If there is no problem with the waterproof performance of the electronic device 2, the internal pressure of the electronic device 2 will not return to the atmospheric pressure level over time but is substantially maintained. In an example, the amount of change according to the degree to which the internal pressure of the electronic device 2 is reduced is measured and, when the measured amount of change is not measured above the threshold level, it may be determined that there is no problem with the waterproof performance of the electronic device 2.

For example, when the second member moves backward along the first member, the air inside the electronic device 2, which is a waterproofing test target, may be suctioned through the air nozzle 127. In other words, the piston forcibly extends the inner space of the body in the syringe 123, thereby securing an excess space capable of being filled with air. The excess space may be filled with the internal air of the electronic device 2 suctioned through the air nozzle 127. In this case, the internal pressure of the electronic device 2 may be reduced.

If a problem arises with the waterproof performance of the electronic device 2, the internal pressure of the electronic device 2 will return to the atmospheric pressure level over time. For example, the amount of change according to the degree to which the internal pressure of the electronic device 2 increases is measured and, when the measured amount of change is measured above the threshold level, it may be determined that a problem occurs with the waterproof performance of the electronic device 2.

If there is no problem with the waterproof performance of the electronic device 2, the internal pressure of the electronic device 2 will not return to the atmospheric pressure level over time but is substantially maintained. For example, the amount of change according to the degree to which the internal pressure of the electronic device 2 increases is measured and, when the measured amount of change is not measured above the threshold level, it may be determined that there is no problem with the waterproof performance of the electronic device 2.

As the adjustment handle part 121 proceeds in the +y direction without being fixed to the stroke fixing part 119, a discharge pressure may act to discharge air. In order to restrict movement in the +y-axis direction in a state in which the adjustment handle part 121 is fixed to the stroke fixing part 119, a substantially right-angled stop jaw 2020 may be provided on the adjustment handle part 121. When the external force controlling the internal pressure of the syringe 123 is removed, the adjustment handle part 121 tries to move in the +y-axis direction by a force trying to return to atmospheric pressure, but the stop jaw 2020 may be caught by the stroke fixing part 119 to prevent the movement of the adjustment handle part 121. This allows the internal pressure of the syringe 123 to be maintained even when the external force is removed. In order for the adjustment handle part 121 to move in the +y-axis direction, the adjustment handle part 121 should be not fixed to the stroke fixing part 119. In a state in which the adjustment handle part 121 is not fixed to the stroke fixing part 119, the adjustment handle part 121 may be moved in direction b so that the stop jaw 2020 provided on the adjustment handle part 121 is removed from the stroke fixing part 119. In this case, the adjustment handle part 121 may move in the +y-axis direction without being restricted by the stroke fixing part 119.

The pressure adjustment part 120 may suction air as a suction pressure acts as the adjustment handle part 121 proceeds in the −y direction in a state in which it is fixed to the stroke fixing part 119. In an embodiment, the state in which the adjustment handle part 121 is fixed to the stroke fixing part 119 may be a state in which the adjustment handle part 121 moves in direction a. If the adjustment handle part 121 moves in direction a, the stop jaw 2020 provided on the adjustment handle part 121 may be caught by the stroke fixing part 119. The adjustment handle part 121 may provide an inclined surface 2010 by C-cut processing the corner portion facing the stop jaw 2020 at the portion fitted into the stroke fixing part 119. The inclined surface 2010 may be, e.g., a surface having an oblique shape other than a right angle. The inclined surface 2010 allows the adjustment handle part 121 to smoothly ride over the stroke fixing part 119 without being caught in the −y-axis direction when an external force is applied. When the adjustment handle part 121 moves in the −y-axis direction, the internal pressure of the syringe 123 may increase.

As described above, when the internal pressure of the electronic device, which is a waterproofing test object changed by air discharge or air suction, is to be maintained, the user may insert and fix the adjustment handle part 121 into the stroke fixing recess provided at the current position.

For example, the adjustment handle part 121 may have a through hole 2030 substantially near the middle on the z-axis so that it may rotate in direction a or direction b. For the rotational movement of the adjustment handle part 121, the shaft 2040 that becomes a substantial rotation shaft may be inserted from one side to the other side of the through hole 2030 provided in the adjustment handle part 121. In an embodiment, two opposite sides of the shaft 2040 passing through the through hole 2030 may be supported by a supporting member 2050 provided parallel to the through hole 2030 inside the syringe mounting part 125. The shaft 2040 may be rotatable within a predetermined angular range in a state of being supported by the supporting member 2050. For example, a slight recess may be dug in the supporting member 2050, allowing the shaft 2040 to be raised.

The stroke fixing part 119 may include stroke fixing recesses 119a, 119b, 119c, 119d, and 119e spaced apart from each other at predetermined intervals. The stroke fixing part 119 may fix the adjustment handle part 121 so that the pressure adjustment part 120 may maintain a constant pressure (e.g., a pressurizing amount or a depressurizing amount). For example, the pressure may be maintained relatively low by the pressure adjustment part 120 as the adjustment handle part 121 is positioned in the +y direction among the plurality of stroke fixing recesses included in the stroke fixing part 119. For example, the pressure may be maintained relatively high by the pressure adjustment part 120 as the adjustment handle part 121 is positioned in the −y direction among the plurality of stroke fixing recesses included in the stroke fixing part 119.

The pressure adjustment part 120 may be fixed by being fitted into one of the plurality of stroke fixing recesses 119a, 119b, 119c, 119d, and 119e included in the stroke fixing part 119 after the adjustment handle part 121 moves in the air suction direction (e.g., −y direction) or the air injection (or discharge) direction (e.g., +y direction) by an external force. In this case, the internal pressure of the electronic device 2 in which the flow path for suctioning or injecting air is formed by sealing may be maintained constant.

The pressure adjustment part 120 may discharge air as an discharge pressure acts as the control handle part 121 proceeds in the +y direction without fixing it to the stroke fixing part 119. The pressure adjustment part 120 may suction air as a suction pressure acts as the control handle part 121 proceeds in the −y direction without fixing it to the stroke fixing part 119. The operation state of the adjustment handle part 121 may be changed into vertical movement due to external force. For example, when the internal pressure of the electronic device 2, which is a waterproofing test target, changed by air discharge or air suction, is to be maintained, the adjustment handle part 121 may be fixed by being fitted into the stroke fixing recess provided at the current position. For example, when the internal pressure of the electronic device 2, which is a waterproofing test target, is to be changed by air discharge or air suction, the adjustment handle part 121 may be separated from the stroke fixing recess.

The lever included in the adjustment handle part 121 may be fitted into and fixed to the stroke fixing recess 119a, 119b, 119c, 119d, and 119e in response to the movement a in the upper direction which is a position where the adjustment handle part 121 is raised by an external force. When the lever is fitted into and fixed to the stroke fixing recess 119a, 119b, 119c, 119d, and 119e, the syringe 123 may enter a movement stop state in which the piston may not move forward or backward. In the movement stop state, the internal pressure of the electronic device 2 may be maintained. The adjustment handle part 121 may be fixed as the lever is fitted into one stroke fixing recess selected from among the plurality of stroke fixing recesses 119a, 119b, 119c, 119d, and 119e in response to the movement a in the upper direction by an external force. The adjustment handle part 121 may increase the convenience of fixing the lever to the selected one stroke fixing recess by applying a spring structure. For example, the spring structure may be designed so that the lever of the adjustment handle part 121 enters the stroke fixing recess and is completely fixed in response to removal of the external force acting on the adjustment handle part 121.

In response to the in the movement b in the lower direction, which is a position where the adjustment handle part 121 is lowered by an external force, the lever included in the adjustment handle part 121 may come off the stroke fixing recesses 119a, 119b, 119c, 119d, and 119e that were fixing it. When the lever comes off the stroke fixing recesses 119a, 119b, 119c, 119d, and 119e, the syringe 123 may be in a movable state in which the piston may move forward or backward. In the movable state, the internal pressure of the electronic device 2 may be changed by the forward movement (e.g., advancing) or backward movement (e.g., retreating) of the adjustment handle 121. The adjustment handle part 121 may increase the convenience of removing the lever from the selected one stroke fixing recess by applying a spring structure. For example, the spring structure may be designed so that the lever of the adjustment handle part 121 exits the stroke fixing recess and is completely separated in response to a slight external force applied to the adjustment handle part 121.

FIG. 21 is a view illustrating an assembly structure for mounting a communication module for measuring pressure in a waterproofing test device (e.g., the waterproofing test device 1 of FIG. 1) according to an embodiment of the disclosure.

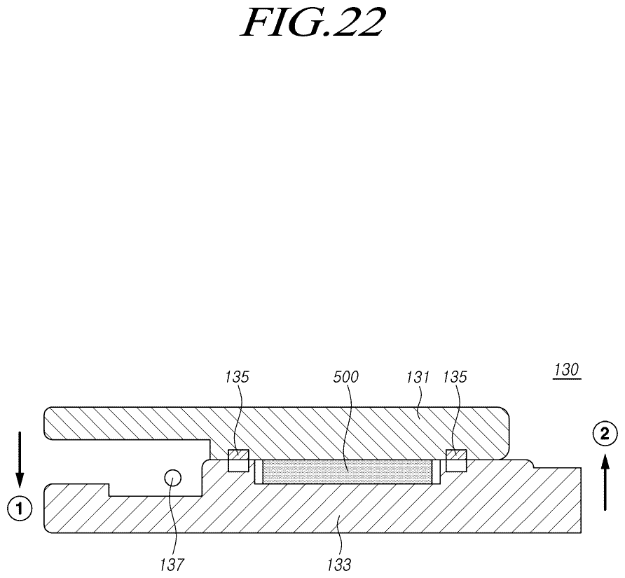

FIG. 22 is a cross-sectional view taken along line A-A′ illustrated in FIG. 21 according to an embodiment of the disclosure.

Referring to FIG. 21 or 22, the module mounting part 130 may have a structure in which a block cover 131 and a block base 133 are assembled in a clip structure. The module mounting part 130 may be equipped with a functional module such as a Bluetooth barometer module 500. The function module may be a communication module configured to perform communication with an external device. For example, the module mounting part 130 may have a shape in which when the handle provided on one side is pressed (\textcircled{1}), the other side opens in the upper direction (\textcircled{2}) with respect to the rotation shaft 137. In this case, the user may press the handle of the module mounting part 130 to open the other side and place the Bluetooth barometer module 500 in the housing having a space therein. The handle part may be designed in a hook type. This may maximize the efficiency of repetitive work. For example, the module mounting part 130 may need to open and close the cover once during one waterproofing test.

The Bluetooth barometer module 500 mounted on the module mounting part 130 may transfer pressure information due to air discharged from a pressure adjustment part (e.g., the pressure adjustment part 120 of FIG. 1) or suctioned by the pressure adjustment part 120 to an external device. The module mounting part 130 may be connected to a passage through which air is discharged from or suctioned into the pressure adjustment part 120 for pressure measurement, through the air hose 153.

In an embodiment, the inner housing provided in the module mounting part 130 in which the Bluetooth barometer module 500 is mounted may have a sealing rubber 135 along its outer rounded portion. The sealing rubber 135 may prevent air from leaking during the waterproofing test.

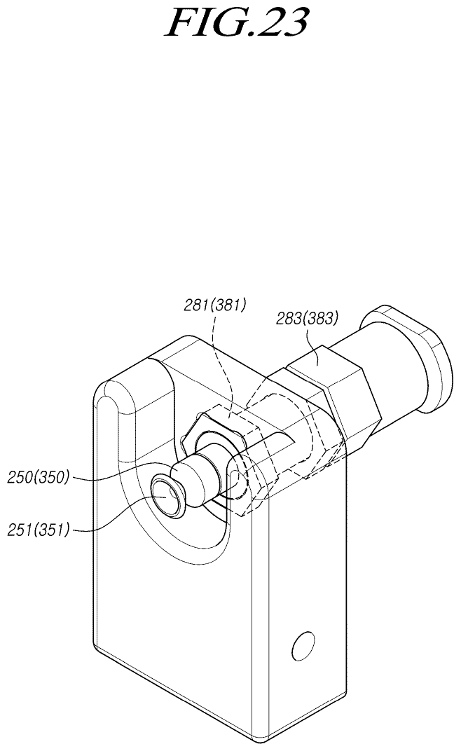

FIG. 23 is a perspective view illustrating a position adjustment part (e.g., the second position adjustment part 280 of FIG. 6 or the second position adjustment part 380 of FIG. 14) included in a clip device (e.g., the basic clip device 20 or the common clip device 30 of FIG. 1) of a waterproofing test device (e.g., the waterproofing test device 1 of FIG. 1) according to an embodiment of the disclosure.

Referring to FIG. 23, the position adjustment part 280, 380 may include a sealing pad (e.g., the first sealing pad 250 of FIG. 6 or the first sealing pad 350 of FIG. 14) installed by penetrating the vicinity of the upper end of the pressing prevention guide part (e.g., the first pressing prevention guide part 260 of FIG. 6 or the second pressing prevention guide part 260 of FIG. 14). The sealing pad 250, 350 may have a nozzle (e.g., the first nozzle 251 of FIG. 9 or the first nozzle 351 of FIG. 15) capable of discharging or suctioning air at the front.

For example, the sealing pad 250, 350 penetrating the vicinity of the upper end of the pressing prevention guide part 260, 360 may proceed forward or backward by the position adjustment part 280, 380. In an embodiment, the position adjustment part 280, 380 may include a first octagonal nut 281, 381 provided with a through hole near the upper end of the pressing prevention guide part 260, 360 penetrated by the sealing pad 250, 350 or a second octagonal nut 283, 383 penetrated by the sealing pad 250, 350 behind the pressing prevention guide part 260, 360. In this case, the user may rotate the sealing pad 250, 350 in a clockwise direction to move it forward, or rotate it in a counterclockwise direction to move it backward.

When the front surface of the sealing pad 250, 350 provided with the nozzle 251, 351 protrudes excessively compared to the front surface of the pressing prevention guide part 260, 360, the air vent hole of the electronic device (e.g., the electronic device 2 of FIG. 11), which is a waterproofing test target, may be damaged by sealing. Therefore, it may be preferable that the front surface of the sealing pad 250, 350 having the nozzle 251, 351 protrudes from the front surface of the pressing prevention guide part 260, 360 to the extent that it may seal the air vent hole of the electronic device 2.

FIG. 24 is a view illustrating a rotating structure of a pad fixing part (e.g., the pad fixing part 211 of FIG. 7 or the pad fixing part 321 of FIG. 13) in a clip device (e.g., the basic clip device 20 or the common clip device 30 of FIG. 1) included in a waterproofing test device (e.g., the waterproofing test device 1 of FIG. 1) according to an embodiment of the disclosure.

In the following description, for convenience, the reference number of the clip device is denoted as “20” and the reference number of the pad fixing part is denoted as 211, but the same or a slight change may be applied to the rotating structure of the pad fixing part 321 coupled to the common type clip device 30.

Referring to FIG. 24, one surface of the pad fixing part 211 may be rotatably coupled to the vicinity of an end of the first clip member (e.g., the first clip member 210 of FIG. 7). The vicinity of the end of the first clip member 210 to which the pad fixing part 211 is rotatably coupled may be, e.g., the vicinity of the end substantially opposite to the end where pressing occurs by an external force. The vicinity of the end of the first clip member 210 is a portion where a distance from the second clip member (e.g., the second clip member 220 of FIG. 7) may increase when the vicinity of the opposite end is pressed by an external force.

According to an embodiment, two opposite ends of the rotation shaft 2410 (e.g., a shaft) transversing in the y-axis direction may be fitted into the fitting holes 2440 and 2450 near the end of the first clip member 210. The rotation shaft 2410 may be fitted to be fixed to the fitting holes 2440 and 2450 provided near the end of the first clip member 210, or may be coupled to be rotated by rolling while being fitted into the fitting holes 2440 and 2450.

The pad fixing part 211 may be fitted into the first clip member 210 by the shaft that operates as the rotation shaft 2410 on the y-axis. To this end, the pad fixing part 211 may have a through hole through which the rotation shaft 2410 passes in the y-axis direction. The pad fixing part 211 may rotate in a predetermined direction (e.g., direction c or direction d) by the rotation shaft 2410. The pad fixing part 211 may rotate around the rotation shaft 2410, e.g., when the rotation shaft 2410 is fixed by fitting into the fitting recesses 2440 and 2450 provided in the first clip member 210. For example, when the rotation shaft 2410 is fitted into the first clip member 210 to be rotatable, the pad fixing part 211 may be rotated together with the rotation shaft 2410. For example, at least one protrusion 2420 and 2430 capable of being fitted into the fitting recesses 2460 and 2470 provided in the pad fixing part 211 may be provided in a vertical direction from the rotation shaft 2410. At least one protrusion 2420 and 2430 provided on the rotation shaft 2410 may be fitted into and fixed to the fitting recesses 2460 and 2470 of the pad fixing part 211.

The rotation of the pad fixing part 211 rotates the first pad 213 fixed to the pad fixing part 211 within a predetermined range. This may stably hold the first surface 21 of the electronic device 2 to be fixed by rotating the first pad 213 at a predetermined angle. In another embodiment, the first surface 21 may have, e.g., a slight inclination angle rather than forming a precisely horizontal plane. In this case, the pad fixing part 211 may be rotated at a required angle around the rotation shaft 2410, so that the first pad 213 may be seated parallel to the first surface 21 of the electronic device 2.

As described above, by allowing the pad fixing part 211 to rotate within a predetermined angular range by the rotation shaft 2410, it is possible to reduce the possibility that the first surface 21 of the mounted electronic device 2 is damaged by the first pad 213.

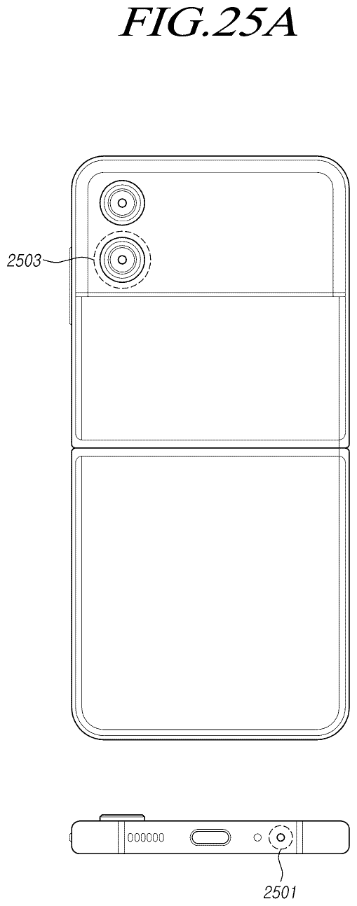

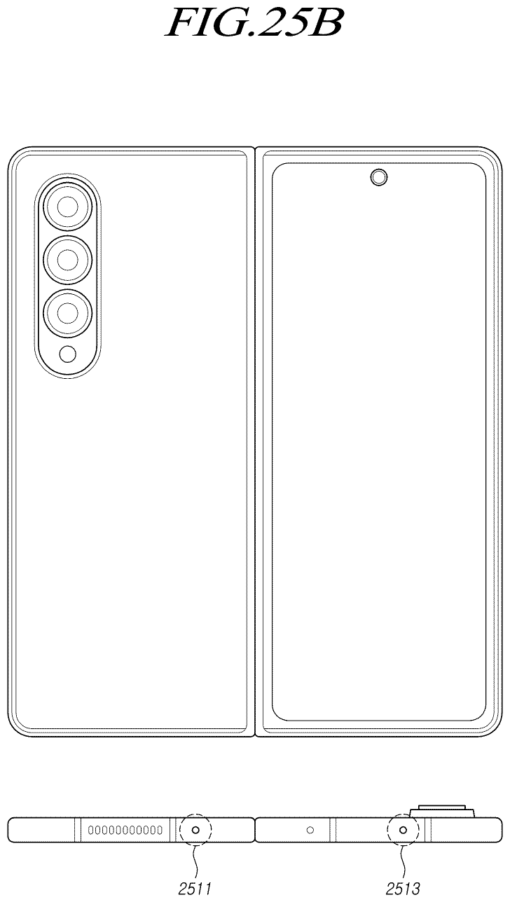

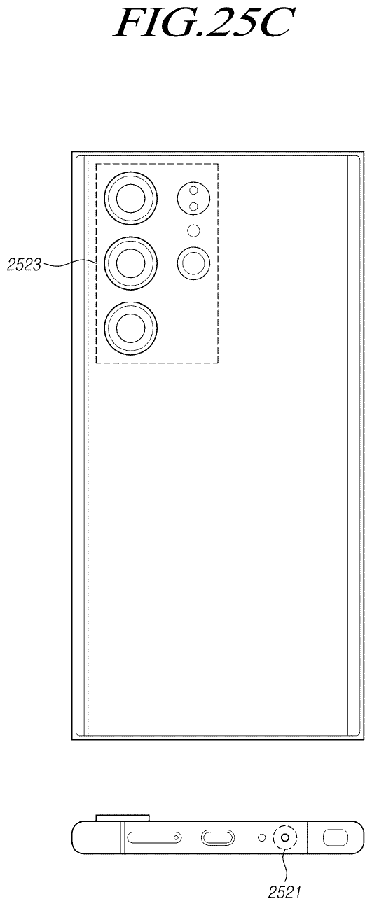

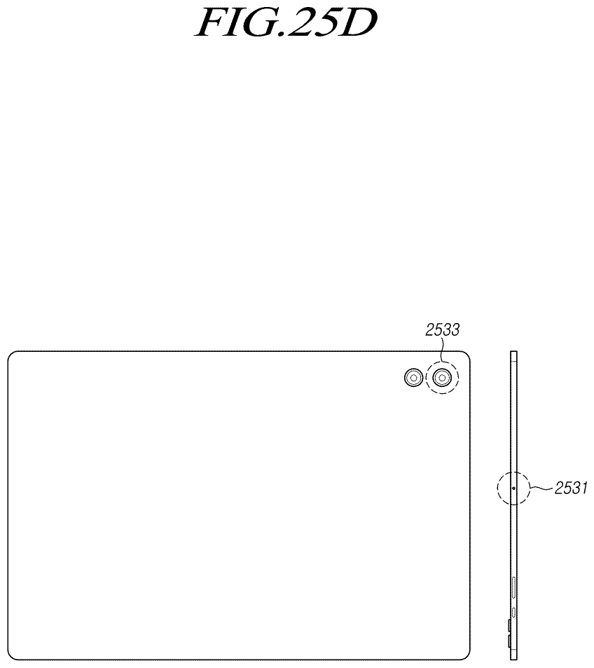

FIGS. 25A, 25B, 25C, and 25D are views illustrating an example of a test target device (e.g., the electronic device 2 of FIG. 11) that may be tested by a waterproofing test device (e.g., the waterproofing test device 1 of FIG. 1) according to various embodiments of the disclosure.

The flip type smartphone illustrated in FIG. 25A may have a first air vent hole 2501 disposed on the lower side. The first air vent hole 2501 may be subjected to a waterproofing test by a basic type clip device (e.g., the basic type clip device 20 of FIG. 1) included in the waterproofing test device 1. A second air vent hole 2503 may be disposed around a camera provided on the rear surface of the flip-type smartphone. The second air vent hole 2503 may be subjected to a waterproofing test by a common type clip device (e.g., the common type clip device 30 of FIG. 1) included in the waterproofing test device 1. A cylindrical dedicated air pad (e.g., the second dedicated air pad 43 of FIG. 1) may be mounted on the common type clip device 30.

A first air vent hole 2511 may be disposed in a lower surface of the left fold in a fold-type smartphone illustrated in FIG. 25B. The first air vent hole 2511 may be subjected to a waterproofing test by a basic type clip device (e.g., the basic type clip device 20 of FIG. 1) included in the waterproofing test device 1. In the fold-type smartphone, a second air vent hole 2513 may be disposed in a lower surface of the left fold. The second air vent hole 2513 may be subjected to a waterproofing test by a common type clip device (e.g., the common type clip device 30 of FIG. 1) included in the waterproofing test device 1. In an embodiment, a cylindrical dedicated air pad (e.g., the second dedicated air pad 43 of FIG. 1) may be mounted on the common type clip device 30.

A first air vent hole 2521 may be disposed in a lower surface of a bar-type smartphone illustrated in FIG. 25C. The first air vent hole 2521 may be subjected to a waterproofing test by a basic type clip device (e.g., the basic type clip device 20 of FIG. 1) included in the waterproofing test device 1. The bar-type smartphone may have a second air vent hole 2523 disposed around a camera widely spread on the rear surface. The second air vent hole 2523 may be subjected to a waterproofing test by a common type clip device (e.g., the common type clip device 30 of FIG. 1) included in the waterproofing test device 1. A flat plate type dedicated air pad (e.g., the first dedicated air pad 41 of FIG. 1) may be mounted on the common type clip device 30.

The first air vent hole 2531 may be disposed in the right surface of the tablet product illustrated in FIG. 25D. The first air vent hole 2531 may be subjected to a waterproofing test by a basic type clip device (e.g., the basic type clip device 20 of FIG. 1) included in the waterproofing test device 1. In the tablet product, a second air vent hole 2533 may be disposed around a camera provided on the rear surface. The second air vent hole 2533 may be subjected to a waterproofing test by a common type clip device (e.g., the common type clip device 30 of FIG. 1) included in the waterproofing test device 1. A cylindrical dedicated air pad (e.g., the second dedicated air pad 43 of FIG. 1) may be mounted on the common type clip device 30.

A waterproofing test device 1 may comprise one or more clip devices 20, 30 including a sealing pad 250, 350 configured to seal at least one air vent hole 2401, 2403, 2411, 2413, 2421, 2423, 2431, 2433 provided in an electronic device 2 by mechanical fastening with the electronic device 2.

As an example, the sealing pad 250, 350 may have one side of a connection hose 240, 340 connected to a rear surface of a surface sealed with the at least one air vent hole 2401, 2403, 2411, 2413, 2421, 2423, 2431, 2433, and be configured to inject external air suctioned through the connection hose 240, 340 into the electronic device 2 through the at least one air vent hole 2401, 2403, 2411, 2413, 2421, 2423, 2431, 2433 in response to a pressure change on an opposite side of the connection hose 240, 340, or to discharge internal air suctioned from the electronic device 2 through the at least one air vent hole 2401, 2403, 2411, 2413, 2421, 2423, 2431, 2433 to an outside through the connection hose 240, 340 in response to the pressure change on the opposite side of the connection hose 240, 340.

The one or more clip devices 20, 30 may have a clip structure configured to mechanically fasten by gripping a first surface 21 and a second surface 23 opposite to the first surface 21 of the electronic device 2.

In an embodiment, the one or more clip devices 20, 30 may include a position adjustment part 261, 263, 280 or 361, 363, 380 configured to vertically and back-and-forth move and fix a position of the sealing pad 250, 350 to align one end of a nozzle 251, 351 of the sealing pad 250, 350 extending from the connection hose 240, 340 to face the at least one air vent hole 2401, 2403, 2411, 2413, 2421, 2423, 2431, 2433.

The one or more clip devices 20, 30 may include a pressing prevention guide part 260, 360 configured to prevent the sealing pad 250, 350 from being a predetermined degree or more due to sealing with the at least one air vent hole 2401, 2403, 2411, 2413, 2421, 2423, 2431, 2433 around the sealing pad 250, 350.

As an example, the one or more clip devices 20, 30 may include an opening 290, 391 provided in a first clip member 210, 310 gripping the first surface 21 to identify a sealing state between the at least one air vent hole 2401, 2403, 2411, 2413, 2421, 2423, 2431, 2433 and the nozzle 251, 351.

As an example, the one or more clip devices 20, 30 may include a first urethane pad 213 provided on an inner surface of a first clip member 210 gripping the first surface 21, and a second urethane pad 223 provided on an inner surface of a second clip member 220 gripping the second surface 23.

In another embodiment, the first clip member 210 may include a fixing pad 211 configured to mount the first urethane pad 213. The fixing pad 211 may be fitted to the first clip member 210 by a shaft 2410 so as to be rotatable on the inner surface of the first clip member 210.

In an embodiment, the one or more clip devices 20, 30 may include a third urethane pad 323 provided on an inner surface of a third clip member 310 gripping the first surface 21, and a fastening part 371, 373, 393 configured to mount a dedicated air pad 40 near one end portion of a fourth clip member 320 gripping the second surface 23.

The third clip member 310 may include a fixing pad 321 configured to mount the third urethane pad 323. The fixing pad 321 may be fitted to the third clip member 310 by a shaft 2410 so as to be rotatable on an inner surface of the third clip member 310.

The dedicated air pad 40 may include a dedicated sealing pad 411, 431 having one surface disposed in a first direction toward the second surface 23 where the at least one air vent hole 2401, 2403, 2411, 2413, 2421, 2423, 2431, 2433 is located, with respect to mounting on the fastening part 371, 373, 393.

As an example, the dedicated air pad 40 may include a flow path tube 413, 433 provided to extend by a predetermined length in a second direction opposite to the first direction from a nozzle 415, 435 of the dedicated sealing pad 411, 431.

As an example, the dedicated air pad 40 may be configured to have a cylindrical shape in consideration of at least one of a position or a shape of the at least one air vent hole 2401, 2403, 2411, 2413, 2421, 2423, 2431, 2433.

As an example, the dedicated air pad 40 may be configured to have a flat plate shape in consideration of at least one of a position or a shape of the at least one air vent hole 2401, 2403, 2411, 2413, 2421, 2423, 2431, 2433.

In an embodiment, the fastening part 371, 373, 393 may include a through hole 393 into which the flow path tube 413, 433 is inserted in the second direction, and first and second fixing pins 371, 373 configured to fix the flow path tube 413, 433 by allowing end portions thereof to tightly contact an outer surface of the flow path tube 413, 433 on two opposite sides of the through hole 393 substantially facing each other.

As an example, the first fixing pin 371 or the second fixing pin 373 may be configured to advance its end portion toward the flow path tube 414, 433 in response to rotation in a clockwise or counterclockwise direction.

As an example, the waterproofing test device 1 may comprise a main body 10 configured to inject the external air or suction the internal air through the at least one air vent hole 2401, 2403, 2411, 2413, 2421, 2423, 2431, 2433 in response to an external force.

The main body 10 may include a pressure adjustment part 120 configured to generate a pressure to discharge the external air filling an inner housing through an air nozzle 127 or to fill the inner housing with the internal air suctioned through the air nozzle 127, in response to the external force.

As an example, the one or more clip devices 20, 30 may include a basic type clip device 20 including a first sealing pad 250 configured to seal a first air vent hole 2401, 2411, 2421, 2431, which is one of the at least one air vent hole 2401, 2403, 2411, 2413, 2421, 2423, 2431, 2433, with a first nozzle 251 by mechanical fastening with the electronic device 2.

In an embodiment, the one or more clip devices 20, 30 may include a common type clip device 30 including a second sealing pad 350 configured to seal a second air vent hole 2403, 2413, 2423, 2433, which is another one of the at least one air vent hole 2401, 2403, 2411, 2413, 2421, 2423, 2431, 2433, with a second nozzle 351 by mechanical fastening with the electronic device 2.

As an example, the first sealing pad 250 may be connected to an opposite side of a first connection hose 240 having one side connected to the air nozzle 127. The first sealing pad 250 may inject the external air transferred through the first connection hose 240 from the air nozzle 127 into the electronic device 2 through the first air vent hole 2401, 2411, 2421, 2431. Alternatively, the first sealing pad 250 may include a passage for suctioning the internal air to be transferred through the first connection hose 240 to the air nozzle 127 from the electronic device 2 through the first air vent hole 2401, 2411, 2421, 2431.

The second sealing pad 350 may be connected to an opposite side of a second connection hose 340 having one side connected to the air nozzle 127. The second sealing pad 350 may inject the external air transferred through the second connection hose 340 from the air nozzle 127 into the electronic device 2 through the second air vent hole 2403, 2413, 2423, 2433. Alternatively, the second sealing pad 350 may include a passage for suctioning the internal air to be transferred through the second connection hose 340 to the air nozzle 127 from the electronic device 2 through the second air vent hole 2403, 2413, 2423, 2433.

According to an example, a waterproofing test device 1 for an electronic device 2 may comprise a main body 10 configured to inject external air into the electronic device 2 or suction internal air of the electronic device 2 through at least one air vent hole 2401, 2403, 2411, 2413, 2421, 2423, 2431, 2433 provided in the electronic device 2 in response to an external force.

As an example, the waterproofing test device 1 may include a basic type clip device 20 including a first sealing pad 250 configured to seal a first air vent hole 2401, 2411, 2421, 2431, which is one of the at least one air vent hole 2401, 2403, 2411, 2413, 2421, 2423, 2431, 2433 by mechanical fastening with the electronic device 2.

The waterproofing test device 1 may include a common type clip device 30 including a second sealing pad 350 configured to seal a second air vent hole 2403, 2413, 2423, 2433, which is another one of the at least one air vent hole 2401, 2403, 2411, 2413, 2421, 2423, 2431, 2433 by mechanical fastening with the electronic device 2.

As an example, the main body 10 may include a pressure adjustment part 120 configured to generate a pressure to discharge the external air filling an inner housing through an air nozzle 127 or to fill the inner housing with the internal air suctioned through the air nozzle 127, in response to the external force.

As an example, the first sealing pad 250 may be connected to an opposite side of a first connection hose 240 having one side connected to the air nozzle 127 and may include a passage for injecting the external air transferred through the first connection hose 240 from the air nozzle 127 into the electronic device 2 through the first air vent hole 2401, 2411, 2421, 2431, or for suctioning the internal air to be transferred through the first connection hose 240 to the air nozzle 127 from the electronic device 2 through the first air vent hole 2401, 2411, 2421, 2431.

In an embodiment, the second sealing pad 350 may be connected to an opposite side of a second connection hose 340 having one side connected to the air nozzle 127 and may include a passage for injecting the external air transferred through the second connection hose 340 from the air nozzle 127 into the electronic device 2 through the second air vent hole 2403, 2413, 2423, 2433, or for suctioning the internal air to be transferred through the second connection hose 340 to the air nozzle 127 from the electronic device 2 through the second air vent hole 2403, 2413, 2423, 2433.

As an example, the main body 10 may include a first mounting part 113 configured to couple the basic type clip device 20 to one side surface and a second mounting part 111 configured to couple the common type clip device 30 to an opposite side surface.

The basic type clip device 20 may include a third mounting part 225 configured to be coupled to the first mounting part 113, and the common type clip device 30 may include a fourth mounting part 315 configured to be coupled to the second mounting part 111.

For example, at least one of the first mounting part 113 or the third mounting part 225 may be a magnet and the other may be a metal, and at least one of the second mounting part 111 or the fourth mounting part 315 may be a magnet and the other may be a metal.

As an example, the main body 10 may include a stroke fixing recess 119 provided for each syringe stroke section that determines a degree of the external force to maintain a pressurizing amount or a depressurizing amount by the pressure adjustment part 120 having a syringe shape so that a set pressure is continuously applied to an inside of the electronic device 2.

In an embodiment, the main body 10 may include an elastic fixing member configured to completely fix a movement of the pressure adjustment part 120 by being fitted into a target stroke fixing recess 119a, 119b, 119c, 119d, 119e provided at the moved position in response to removal of the external force after the pressure adjustment part 120 is moved by the external force.

As an example, the stroke fixing recess 119 in the main body 10 may be provided in consideration of the internal volume or waterproof guarantee level of the electronic device 2.

As an example, the main body 10 may include a module mounting part 130 in which a block base 133 and a block cover 131 are assembled in a clip structure, and a space in which a Bluetooth barometer module 500 is mounted may be provided between the block base 133 and the block cover 131.

As an example, the basic type clip device 20 or the common type clip device 30 may have a clip structure that grips the upper surface 21 and the lower surface 23 of the electronic device 2 to form a mechanical fastening.

As an example, the basic type clip device 20 may include a first position adjustment part 261, 263 configured to vertically move the first sealing pad 250 to be aligned so as to face the first air vent holes 2401, 2411, 2421, 2431.

As an example, the basic type clip device 20 may include a second position adjustment part 280 configured to move the first sealing pad 250 back and forth to be fixed for sealing with the first air vent holes 2401, 2411, 2421, 2431.

The basic type clip device 20 may include a first pressing prevention guide part 260 configured to prevent the first sealing pad 250 from being pressed to a predetermined degree or more by sealing with the first air vent hole 2401, 2411, 2421, and 2431 around the first sealing pad 250.

As an example, the first air vent hole 2401, 2411, 2421, 2431 may be located on a side surface of the electronic device 2.

As an example, the basic type clip device 20 may include an opening 290 provided to allow a sealing state of the first air vent hole 2401, 2411, 2421, 2431 and the first sealing pad 250 to be identified in an upper clip member 210 gripping the upper surface 21 of the electronic device 2 in the clip structure.

As an example, the basic type clip device 20 may include a first urethane pad 213 provided on an inner surface of an upper clip member 210 gripping an upper surface 21 of the electronic device 2 in the clip structure, and a second urethane pad 223 provided on an inner surface of a lower clip member 220 gripping an lower surface 23 of the electronic device 2 in the clip structure.

The common type clip device 30 may include a third position adjustment part 361, 363 configured to vertically move the second sealing pad 350 to be aligned so as to face the second air vent hole 2403, 2413, 2423, 2433.

As an example, the common type clip device 30 may include a fourth position adjustment part 380 configured to move the second sealing pad 350 back and forth to be fixed for sealing with the second air vent hole 2403, 2413, 2423, 2433.

As an example, the common type clip device 30 may include a second pressing prevention guide part 360 configured to prevent the second sealing pad 350 from being pressed to a predetermined degree or more by sealing with the second air vent hole 2403, 2413, 2423, and 2433 around the second sealing pad 350.

As an example, the second air vent hole 2403, 2413, 2423, 2433 may be located on a side surface of the electronic device 2.

In an embodiment, the common type clip device 30 may include an opening 391 provided to allow a sealing state of the second air vent hole 2403, 2413, 2423, 2433 and the second sealing pad 350 to be identified in an upper clip member 310 gripping the upper surface 21 of the electronic device 2 in the clip structure.

As an example, the common type clip device 30 may include a third urethane pad 323 provided on an inner surface of a third clip member 310 gripping the first surface 21 of the electronic device 2 in the clip structure.

As an example, the common type clip device 30 may include a fastening member 371, 373, 393 configured to mount a dedicated air pad 40 near one end portion of the fourth clip member 320 gripping the second face 23 of the electronic device 2 corresponding to a rear surface of the first surface 21 in the clip structure.

As an example, the dedicated air pad 40 may include a third sealing pad 411, 431 having one surface disposed in a first direction toward the second surface 23 of the electronic device 2 where the second air vent hole 2403, 2413, 2423, 2433 is located, with respect to mounting on the fastening part 371, 373, 393.

The dedicated air pad 40 may include a flow path tube 413, 433 provided to extend by a predetermined length in a second direction opposite to the first direction from a nozzle 415, 435 of the third sealing pad 411, 431.

As an example, the third sealing pad 411, 431 may be configured to have a shape of either a cylinder or a flat plate in consideration at least one of a position or shape of the second air vent hole 2403, 2413, 2423, 2433.

As an example, the fastening part 371, 373, 393 may include a through hole 393 into which the flow path tube 413, 433 is inserted in the second direction, and first and second fixing pins 371, 373 configured to fix the flow path tube 413, 433 by allowing end portions thereof to tightly contact an outer surface of the flow path tube 413, 433 on two opposite sides of the through hole 393 substantially facing each other.

The first fixing pin 371 or the second fixing pin 373 may be configured to advance its end portion toward the flow path tube 413, 433 in response to rotation in a clockwise or counterclockwise direction.

The terms as used herein are provided merely to describe some embodiments thereof, but are not intended to limit the disclosure. As used herein, the singular forms “a,” “an,” and “the” are intended to include the plural forms as well, unless the context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, the term ‘and/or’ should be understood as encompassing any and all possible combinations by one or more of the enumerated items. As used herein, the terms “include,” “have,” and “comprise” are used merely to designate the presence of the feature, component, part, or a combination thereof described herein, but use of the term does not exclude the likelihood of presence or adding one or more other features, components, parts, or combinations thereof. As used herein, the terms “first” and “second” may modify various components regardless of importance and/or order and are used to distinguish a component from another without limiting the components.

As used herein, the terms “configured to” may be interchangeably used with the terms “suitable for,” “having the capacity to,” “designed to,” “adapted to,” “made to,” or “capable of” depending on circumstances. The term “configured to” does not essentially mean “specifically designed in hardware to.” Rather, the term “configured to” may mean that a device can perform an operation together with another device or parts. For example, a ‘device configured (or set) to perform A, B, and C’ may be a dedicated device to perform the corresponding operation or may mean a general-purpose device capable of various operations including the corresponding operation.

Meanwhile, the terms “upper side”, “lower side”, and “front and rear directions” used in the disclosure are defined with respect to the drawings, and the shape and position of each component are not limited by these terms.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A waterproofing test device comprising:
one or more clip devices including a sealing pad configured to seal at least one air vent hole provided in an electronic device by mechanical fastening with the electronic device,
wherein the sealing pad has one side of a connection hose connected to a rear surface of a surface sealed with the at least one air vent hole, and is configured to inject external air suctioned through the connection hose into the electronic device through the at least one air vent hole in response to a pressure change on an opposite side of the connection hose, or to discharge internal air suctioned from the electronic device through the at least one air vent hole to an outside through the connection hose in response to the pressure change on the opposite side of the connection hose.

2. The waterproofing test device of claim 1, wherein the one or more clip devices has a clip structure configured to mechanically fasten by gripping a first surface and a second surface opposite to the first surface of the electronic device, and includes:
a position adjustment part configured to vertically and back-and-forth move and fix a position of the sealing pad to align one end of a nozzle of the sealing pad extending from the connection hose to face the at least one air vent hole; and
a pressing prevention guide part configured to prevent the sealing pad from being pressed to a predetermined degree or more due to sealing with the at least one air vent hole around the sealing pad.

3. The waterproofing test device of claim 2, wherein the one or more clip devices includes an opening provided in a first clip member gripping the first surface to identify a sealing state between the at least one air vent hole and the nozzle.

4. The waterproofing test device of claim 2, wherein the one or more clip devices include:
a first urethane pad provided on an inner surface of a first clip member gripping the first surface; and
a second urethane pad provided on an inner surface of a second clip member gripping the second surface.

5. The waterproofing test device of claim 4,
wherein the first clip member includes a fixing pad configured to mount the first urethane pad, and
wherein the fixing pad is fitted to the first clip member by a shaft so as to be rotatable on the inner surface of the first clip member.

6. The waterproofing test device of claim 2, wherein the one or more clip devices include:
a third urethane pad provided on an inner surface of a third clip member gripping the first surface; and
a fastening part configured to mount a dedicated air pad near one end portion of a fourth clip member gripping the second surface.

7. The waterproofing test device of claim 6,
wherein the third clip member includes a fixing pad configured to mount the third urethane pad, and
wherein the fixing pad is fitted to the third clip member by a shaft so as to be rotatable on the inner surface of the third clip member.

8. The waterproofing test device of claim 6, wherein the dedicated air pad includes:
a dedicated sealing pad having one surface disposed in a first direction toward the second surface where the at least one air vent hole is located, with respect to mounting on the fastening part; and
a flow path tube provided to extend by a predetermined length in a second direction opposite to the first direction from a nozzle of the dedicated sealing pad.

9. The waterproofing test device of claim 8, wherein the dedicated air pad is configured to have a cylindrical shape in consideration of at least one of a position or a shape of the at least one air vent hole.

10. The waterproofing test device of claim 8, wherein the dedicated air pad is configured to have a flat plate shape in consideration of at least one of a position or a shape of the at least one air vent hole.

11. The waterproofing test device of claim 6, wherein the dedicated air pad is configured to have a cylindrical shape in consideration of at least one of a position or a shape of the at least one air vent hole.

12. The waterproofing test device of claim 6, wherein the dedicated air pad is configured to have a flat plate shape in consideration of at least one of a position or a shape of the at least one air vent hole.

13. The waterproofing test device of claim 8, wherein the fastening part includes:
a through hole into which the flow path tube is inserted in the second direction; and
first and second fixing pins configured to fix the flow path tube by allowing end portions thereof to tightly contact an outer surface of the flow path tube on two opposite sides of the through hole substantially facing each other.

14. The waterproofing test device of claim 13, wherein the first fixing pin or the second fixing pin is configured to advance its end portion toward the flow path tube in response to rotation in a clockwise or counterclockwise direction.

15. The waterproofing test device of claim 1, further comprising:
a main body configured to inject the external air or suction the internal air through the at least one air vent hole in response to an external force,
wherein the main body includes a pressure adjustment part configured to generate a pressure to discharge the external air filling an inner housing through an air nozzle or to fill the inner housing with the internal air suctioned through the air nozzle, in response to the external force.

16. The waterproofing test device of claim 15, wherein the one or more clip devices include:
a basic type clip device including a first sealing pad configured to seal a first air vent hole, which is one of the at least one air vent hole, with a first nozzle by mechanical fastening with the electronic device; and
a common type clip device including a second sealing pad configured to seal a second air vent hole, which is another one of the at least one air vent hole, with a second nozzle by mechanical fastening with the electronic device.

17. The waterproofing test device of claim 16,
wherein the first sealing pad is connected to an opposite side of a first connection hose having one side connected to the air nozzle, and includes a passage for injecting the external air transferred through the first connection hose from the air nozzle into the electronic device through the first air vent hole, or for suctioning the internal air to be transferred through the first connection hose to the air nozzle from the electronic device through the first air vent hole, and
wherein the second sealing pad is connected to an opposite side of a second connection hose having one side connected to the air nozzle, and includes a passage for injecting the external air transferred through the second connection hose from the air nozzle into the electronic device through the second air vent hole, or for suctioning the internal air to be transferred through the second connection hose to the air nozzle from the electronic device through the second air vent hole.

18. The waterproofing test device of claim 1, wherein the one or more clip devices include:
a basic type clip device including a first sealing pad configured to seal a first air vent hole, which is one of the at least one air vent hole, with a first nozzle by mechanical fastening with the electronic device; and
a common type clip device including a second sealing pad configured to seal a second air vent hole, which is another one of the at least one air vent hole, with a second nozzle by mechanical fastening with the electronic device.
